(19) United States
(12) Patent Application Publication
(10) Pub. No.: US 2025/0227933 A1
(43) Pub. Date: Jul. 10, 2025

(54) NON-VOLATILE MEMORY DEVICE, METHOD OF MANUFACTURING THE SAME, AND MEMORY SYSTEM COMPRISING THE SAME

(71) Applicant: SAMSUNG ELECTRONICS CO., LTD., Suwon-si (KR)

(72) Inventors: Garam Kim, Suwon-si (KR); Sangwon Park, Suwon-si (KR); Sangbum Yun, Suwon-si (KR)

(21) Appl. No.: 19/005,967

(22) Filed: Dec. 30, 2024

(30) Foreign Application Priority Data
Jan. 9, 2024 (KR) 10-2024-0003626

(51) Int. Cl. H10B 43/40; G11C 16/04; H01L 25/07; H10B 41/27; H10B 41/35; H10B 41/41; H10B 43/27; H10B 43/35; H10B 80/00

(52) U.S. Cl. CPC H10B 43/40; G11C 16/0483; H01L 25/074; H10B 41/27; H10B 41/35; H10B 41/41; H10B 43/27; H10B 43/35; H10B 80/00; H01L 2225/06506

(57) ABSTRACT

A non-volatile memory device includes a peripheral circuit structure including a peripheral circuit, a lower insulating structure, and lower bonding pads, a cell array structure having a cell region and a peripheral connection region, the cell array structure including an upper insulating structure contacting the lower insulating structure, an upper bonding pad bonded to the lower bonding pads, a cell stack in the cell region of the upper insulating structure, a common source line layer arranged on the cell stack and including a common source opening, a base insulating layer filling the common source opening and covering the common source line layer, and cell channel structures penetrating the cell stack and extending into the common source line layer, and a pad pattern extending from the peripheral connection region to the cell region and partially overlapping the common source opening in a vertical direction, on the cell array structure.

### CROSS-REFERENCE TO RELATED APPLICATION

This application claims priority under 35 U.S.C. § 119 to Korean Patent Application No. 10-2024-0003626, filed on Jan. 9, 2024, in the Korean Intellectual Property Office, the disclosure of which is incorporated by reference herein in its entirety.

### BACKGROUND

Consumers require non-volatile memory devices with excellent performance, small sizes, and reasonable price. Therefore, a three-dimensional non-volatile memory device, in which multiple memory cells are vertically arranged, has been suggested to achieve high integration.

### SUMMARY

The disclosure provides a non-volatile memory device with operational reliability and a memory system including the non-volatile memory device.

According to an aspect of the disclosure, there is provided a non-volatile memory device including a peripheral circuit structure including a peripheral circuit, a lower insulating structure covering the peripheral circuit, and lower bonding pads on an upper surface of the lower insulating structure and electrically connected to the peripheral circuit, a cell array structure having a cell region and a peripheral connection region, the cell array structure including an upper insulating structure contacting the lower insulating structure, an upper bonding pad arranged on a lower surface of the upper insulating structure and bonded to the lower bonding pads, a cell stack arranged in the cell region of the upper insulating structure, a common source line layer arranged on the cell stack and including a common source opening, a base insulating layer filling the common source opening and covering the common source line layer, and cell channel structures penetrating the cell stack and extending into the common source line layer, and a pad pattern extending from the peripheral connection region to the cell region and partially overlapping the common source opening in a vertical direction, on the cell array structure.

According to another aspect of the disclosure, there is provided a non-volatile memory device including a peripheral circuit structure including a peripheral circuit, a lower insulating structure covering the peripheral circuit, and a plurality of lower bonding pads on an upper surface of the lower insulating structure and electrically connected to the peripheral circuit, a cell array structure having a cell region and a peripheral connection region, the cell array structure including an upper insulating structure contacting the lower insulating structure, a plurality of upper bonding pads arranged on a lower surface of the upper insulating structure and respectively bonded to the plurality of lower bonding pads, a cell stack arranged in the cell region of the upper insulating structure, a common source line layer arranged on the cell stack in the cell region and including a common source opening, a base insulating layer filling the common source opening and covering the common source line layer, a plurality of cell channel structures penetrating the cell stack and extending into the common source line layer, and a through contact plug connected to any one of the plurality of upper bonding pads in the peripheral connection region, a pad pattern extending from the peripheral connection region to the cell region on the cell array structure, wherein the pad pattern partially overlaps the cell stack in a vertical direction, but does not overlap the common source line layer in the vertical direction, and a pad connection via connecting between the through contact plug and the pad pattern.

According to another aspect of the disclosure, there is provided a memory system including a non-volatile memory device including a peripheral circuit structure including a peripheral circuit, a lower insulating structure covering the peripheral circuit, and a plurality of lower bonding pads arranged on an upper surface of the lower insulating structure and electrically connected to the peripheral circuit, a cell array structure bonded to the peripheral circuit structure and including a cell stack region, which includes a real cell region and a dummy cell region, and a peripheral circuit region, and a pad pattern extending, on the cell array structure, from the peripheral connection region to the dummy cell region, and a memory controller electrically connected to the non-volatile memory device through the pad pattern and configured to control the non-volatile memory device, wherein the cell array structure includes an upper insulating structure contacting the lower insulating structure, a plurality of upper bonding pads arranged on a lower surface of the upper insulating structure and respectively bonded to the plurality of lower bonding pads, a cell stack arranged in the cell stack region of the upper insulating structure, a common source line layer arranged on the cell stack, including a common source opening in the dummy cell region, and not overlapping the pad pattern in a vertical direction, a base insulating layer filling the common source opening and covering the common source line layer, a plurality of cell channel structures penetrating the cell stack in the real cell region and extending into the common source line layer, a through contact plug electrically connecting, in the peripheral connection region, between the pad pattern and any one of the plurality of upper bonding pads, and a pad connection via connecting between the through contact plug and the pad pattern.

### BRIEF DESCRIPTION OF THE DRAWINGS

Embodiments of the disclosure will be more clearly understood from the following detailed description taken in conjunction with the accompanying drawings in which:

FIG. 1 is a block diagram of a non-volatile memory device according to some embodiments;

FIG. 2 is a schematic perspective view of a non-volatile memory device according to some embodiments;

FIG. 3 is an equivalent circuit diagram of a memory cell array of a non-volatile memory device, according to some embodiments;

FIGS. 4A and 4B are schematic layouts of a non-volatile memory device according to some embodiments;

FIGS. 5A to 5I are cross-sectional views of a non-volatile memory device according to some embodiments;

FIGS. 6A and 6B are cross-sectional views of a non-volatile memory device according to some embodiments;

FIGS. 7A to 7C are enlarged cross-sectional views of a cell channel structure according to some embodiments;

FIGS. 8 to 12 are cross-sectional views of a non-volatile memory device according to some embodiments;

FIG. 13 schematically illustrates a memory system including a non-volatile memory device, according to some embodiments;

FIG. 14 is a schematic perspective view of a memory system including a non-volatile memory device, according to some embodiments; and

FIG. 15 is a schematic cross-sectional view of a semiconductor package according to some embodiments.

### DETAILED DESCRIPTION

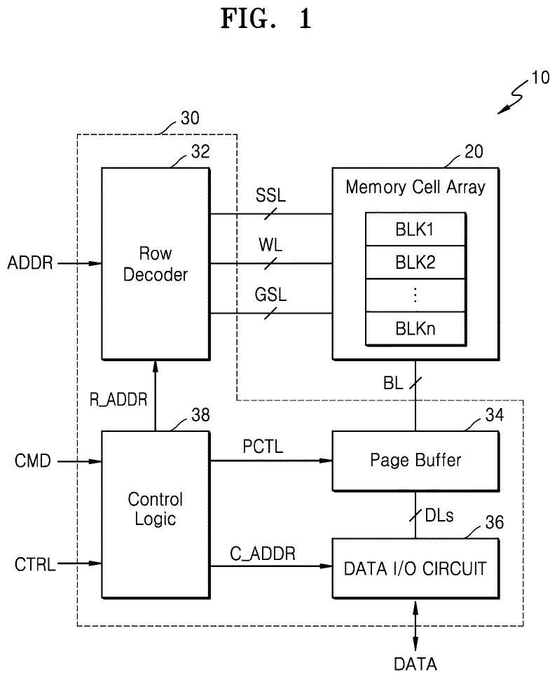

FIG. 1 is a block diagram of a non-volatile memory device according to some embodiments.

Referring to FIG. 1, a non-volatile memory device 10 includes a memory cell array 20 and a peripheral circuit 30. The memory cell array 20 includes a plurality of memory cell blocks BLK1, BLK2, . . . , and BLKn. The memory cell blocks BLK1, BLK2, . . . , and BLKn may each include a plurality of memory cells. The memory cell blocks BLK1, BLK2, . . . , and BLKn may be connected to the peripheral circuit 30 through a bit line BL, a word line WL, a string selection line SSL, and a ground selection line GSL.

The peripheral circuit 30 includes a row decoder 32, a page buffer 34, a data input/output circuit 36, and a control logic 38. In some embodiments, the peripheral circuit 30 may further include an input/output interface, a column logic, a voltage generator, a pre-decoder, a temperature sensor, a command decoder, an address decoder, an amplifying circuit, and the like.

The memory cell array 20 may be connected to the page buffer 34 through the bit line BL and to the row decoder 32 through the word line WL, the string selection line SSL, and the ground selection line GSL. In the memory cell array 20, the memory cells respectively included in the memory cell blocks BLK1, BLK2, . . . , and BLKn may each be a flash memory cell. The memory cell array 20 may include a three-dimensional memory cell array. The three-dimensional memory cell array may include a plurality of NAND strings extending in a vertical direction, and each NAND string may include a plurality of memory cells connected to the word lines WL vertically stacked on a substrate.

The peripheral circuit 30 may receive an address ADDR, a command CMD, and a control signal CTRL from the outside of the non-volatile memory device 10 and may receive/transmit data DATA from/to a device outside the non-volatile memory device 10.

The row decoder 32 may select at least one of the memory cell blocks BLK1, BLK2, . . . , and BLKn in response to an external address ADDR and select a word line WL, a string selection line SSL, and a ground selection line GSL of the selected memory cell block. The row decoder 32 may transmit a voltage for performing a memory operation to the word line WL of the selected memory cell block.

The page buffer 34 may be connected to the memory cell array 20 through the bit line BL. The page buffer 34 may function as a write driver during a program operation and thus may apply, to the bit line BL, a voltage according to data DATA to be stored in the memory cell array 20, and the page buffer 34 may function as a sense amplifier during a read operation and thus may detect data DATA stored in the memory cell array 20. The page buffer 34 may operate according to a control signal PCTL provided from the control logic 38.

The data input/output circuit 36 may be connected to the page buffer 34 through data lines DLs. During the program operation, the data input/output circuit 36 may receive data DATA from a memory controller (not shown) and provide program data DATA to the page buffer 34 based on a column address C_ADDR provided from the control logic 38. During the read operation, the data input/output circuit 36 may provide the memory controller with the read data DATA that is stored in the page buffer 34, based on a column address C_ADDR provided from the control logic 38.

The data input/output circuit 36 may transmit an input address or command to the control logic 38 or the row decoder 32. The peripheral circuit 30 may further include an electrostatic discharge (ESD) circuit and a pull-up/pull-down driver.

The control logic 38 may receive the command CMD and the control signal CTRL from the memory controller. The control logic 38 may provide a row address R_ADDR to the row decoder 32 and a column address C_ADDR to the data input/output circuit 36. The control logic 38 may generate a variety of internal control signals used in the non-volatile memory device 10, in response to the control signal CTRL. For example, the control logic 38 may adjust a voltage level provided to the word line WL and the bit line BL during a memory operation, such as a program operation or an erase operation.

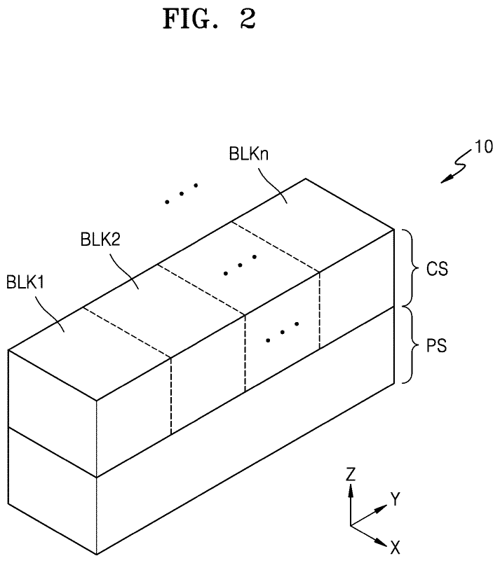

FIG. 2 is a schematic perspective view of a non-volatile memory device according to some embodiments.

Referring to FIG. 2, the non-volatile memory device 10 includes a cell array structure CS and a peripheral circuit structure PS which overlap each other in a vertical direction (a Z direction). The cell array structure CS may include the memory cell array 20 described with reference to FIG. 1. The peripheral circuit structure PS may include the peripheral circuit 30 described with reference to FIG. 1.

The cell array structure CS includes a plurality of memory cell blocks BLK1, BLK2, . . . , and BLKn. The memory cell blocks BLK1, BLK2, . . . , and BLKn may each include a plurality of memory cells that are three-dimensionally arranged.

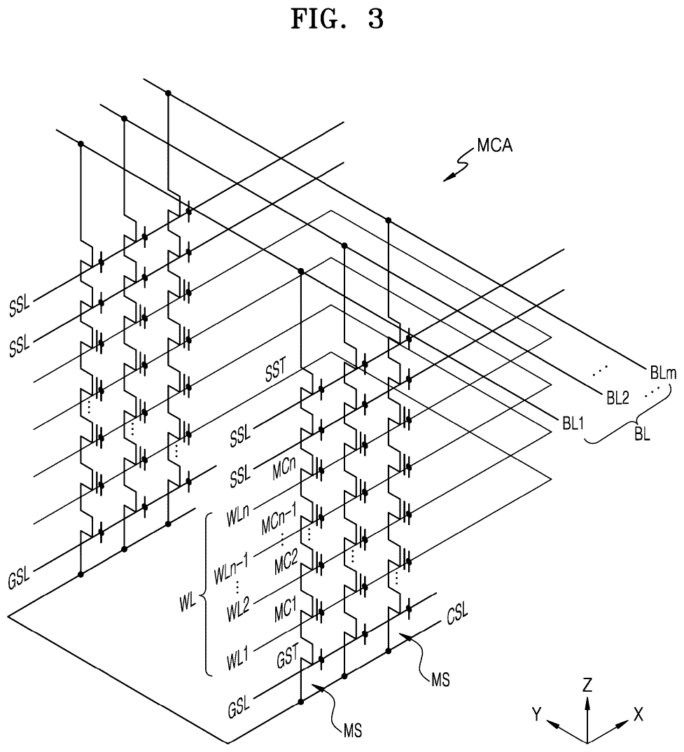

FIG. 3 is an equivalent circuit diagram of a memory cell array of a non-volatile memory device, according to some embodiments.

Referring to FIG. 3, a memory cell array MCA includes a plurality of memory cell strings MS. The memory cell array MCA may include at least a portion of the memory cell array 20 described with reference to FIG. 1. In some embodiments, the memory cell array MCA may include at least a portion of one of the memory cell blocks BLK1, BLK2, . . . , and BLKn included in the memory cell array 20 described with reference to FIG. 1.

Each of the memory cell strings MS may extend in the vertical direction (the Z direction). The memory cell array MCA includes a plurality of word lines WL (WL: WL1, WL2, . . . , WLn−1, and WLn), a plurality of bit lines BL (BL: BL1, BL2, . . . , and BLm), at least one string selection line SSL, at least one ground selection line GSL, and a common source line CSL. Each of the word lines WL (WL: WL1, WL2, . . . , WLn−1, and WLn) may extend in a first horizontal direction (an X direction), and each of the bit lines BL (BL: BL1, BL2, . . . , and BLm) may extend in a second horizontal direction (a Y direction) that is orthogonal to the first horizontal direction (the X direction). Each of at least one string selection line SSL and at least one ground selection line GSL may extend in the same direction as the extension direction of the word lines WL (WL: WL1, WL2, . . . , WLn−1, and WLn), for example, in the first horizontal direction (the X direction). The memory cell strings MS may be formed between the bit lines BL (BL: BL1, BL2, . . . , and BLm) and the common source line CSL. FIG. 3 shows that each memory cell string MS includes two string selection lines SSL, but one or more embodiments are not limited thereto. For example, each memory cell string MS may include one string selection line SSL.

Each memory cell string MS includes a string selection transistor SST, a ground selection transistor GST, and a plurality of memory cell transistors MC1, MC2, . . . , MCn−1, and MCn. A drain area of the string selection transistor SST may be connected to the bit line BL (BL: BL1, BL2, . . . , and BLm), and a source area of the ground selection transistor GST may be connected to the common source line CSL. The common source line CSL may be an area where source areas of the ground selection transistors GST are commonly connected.

The string selection transistor SST may be connected to the string selection line SSL, and the ground selection transistor GST may be connected to the ground selection line GSL. The memory cell transistors MC1, MC2, . . . , MCn−1, and MCn may be connected to the word lines WL (WL: WL1, WL2, . . . , WLn−1, and WLn), respectively.

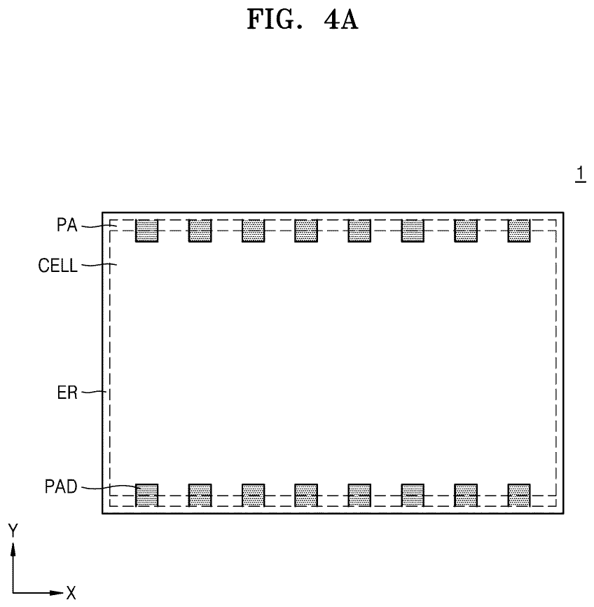

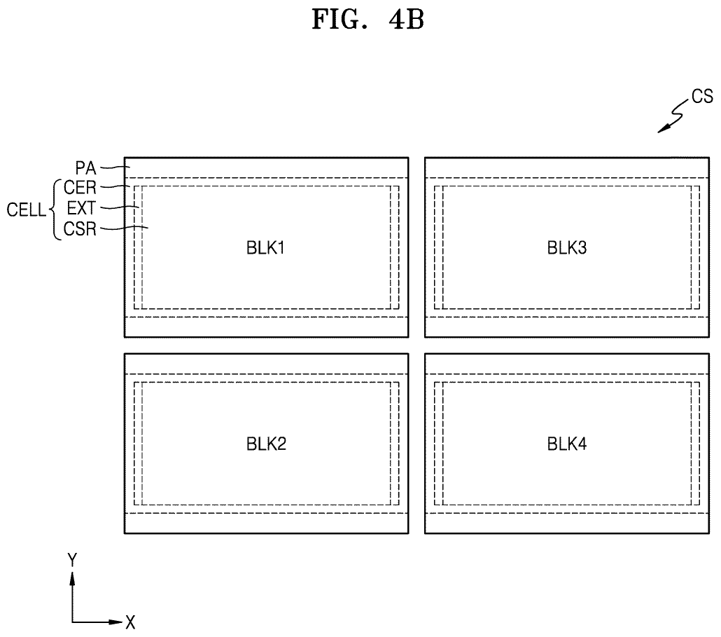

FIGS. 4A and 4B are schematic layouts of a non-volatile memory device according to some embodiments.

Referring to FIG. 4A, a non-volatile memory device 1 may planarly include a cell region CELL and an edge region ER surrounding the cell region CELL. A peripheral connection region PA may be positioned between the cell region CELL and the edge region ER. In some embodiments, the peripheral connection region PA may be between the cell region CELL and the edge region ER in the second horizontal direction (the Y direction) and may extend in the first horizontal direction (the X direction). In some embodiments, the peripheral connection region PA may not be positioned between the cell region CELL and the edge region ER in the second horizontal direction (the Y direction).

The non-volatile memory device 1 includes a plurality of pad patterns PAD. In some embodiments, the pad patterns PAD may be arranged adjacent to both side portions of the edge region ER that are opposite to each other in the second horizontal direction (the Y direction). The pad patterns PAD may be arranged in a line along the peripheral connection region PA. In some embodiments, the pad patterns PAD may be arranged in a line in the first horizontal direction (the X direction). Each pad pattern PAD may be arranged over the peripheral connection region PA and the cell region CELL. For example, a portion of each pad pattern PAD may be located in the peripheral connection region PA, and the other portions of the pad pattern PAD may be located in the cell region CELL.

Referring to FIGS. 4A and 4B together, the non-volatile memory device 1 includes the cell array structure CS. The non-volatile memory device 1 may be the non-volatile memory device 10 of FIG. 1, and the cell array structure CS may be the cell array structure CS of FIG. 2.

The cell array structure CS includes a plurality of memory cell blocks BLK1, BLK2, BLK3, and BLK4. The memory cell blocks BLK1, BLK2, BLK3, and BLK4 may be arranged in rows and columns along the first horizontal direction (the X direction) and the second horizontal direction (the Y direction). The first horizontal direction (the X direction) may be an extension direction of each word line WL (WL: WL1, WL2, . . . , WLn−1, and WLn) illustrated in FIG. 3, and the second horizontal direction (the Y direction) may be an extension direction of each bit line BL (BL: BL1, BL2, . . . , and BLm). Each of the memory cell blocks BLK1, BLK2, BLK3, and BLK4 may include a plurality of memory cells.

Each of the memory cell blocks BLK1, BLK2, BLK3, and BLK4 includes a cell region CELL and a cell connection region EXT. In some embodiments, each of the memory cell blocks BLK1, BLK2, BLK3, and BLK4 includes a cell region CELL and a peripheral connection region PA. The peripheral connection region PA may be in one or both sides of the cell region CELL in the second horizontal direction (the Y direction). For example, in the peripheral connection region PA, components for connecting the peripheral circuit structure PS described with reference to FIG. 2 to the cell region CELL and/or the cell connection region EXT may be arranged. Alternatively, for example, at least a portion of the peripheral circuit 30 described with reference to FIG. 1 may be arranged in the peripheral connection region PA.

The cell region CELL includes a cell stack region CSR, a pair of cell connection regions EXT on both sides of the cell stack region CSR, and a cell edge region CER surrounding the cell stack region CSR and the pair of cell connection regions EXT. The pair of cell connection regions EXT may extend, in the second horizontal direction (the Y direction), on both sides of the cell stack region CSR that lie in the first horizontal direction (the X direction). In some embodiments, the cell region CELL includes the cell stack region CSR, the cell connection region EXT on a side of the cell stack region CSR, and the cell edge region CER surrounding the cell stack region CSR and the cell connection region EXT. In some embodiments, the cell region CELL includes the cell stack region CSR, two pairs of cell connection regions EXT on both sides of the cell stack region CSR in the first horizontal direction (the X direction) and both sides of the cell stack region CSR in the second horizontal direction (the Y direction), and the cell edge region CER surrounding the cell stack region CSR and the two pairs of cell connection regions EXT. The cell edge region CER may be between the cell stack region CSR and the peripheral connection region PA.

The peripheral connection region PA of FIG. 4A may indicate only a portion of the peripheral connection region PA of FIG. 4B that is adjacent to the edge region ER of the non-volatile memory device 1. For example, in the cell region CELL of FIG. 4A, the cell stack region CSR, the cell connection region EXT, and the cell edge region CER of each of the memory cell blocks BLK1, BLK2, BLK3, and BLK4 of FIG. 4B and at least a portion of the peripheral connection region PA of each of the memory cell blocks BLK1, BLK2, BLK3, and BLK4 of FIG. 4B may be arranged.

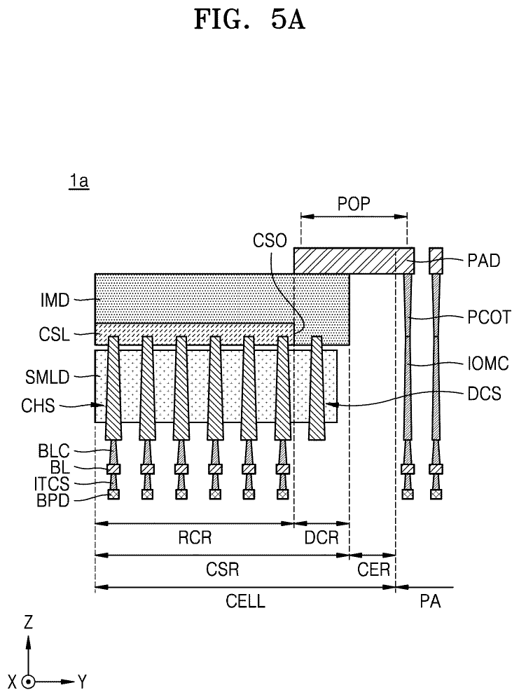

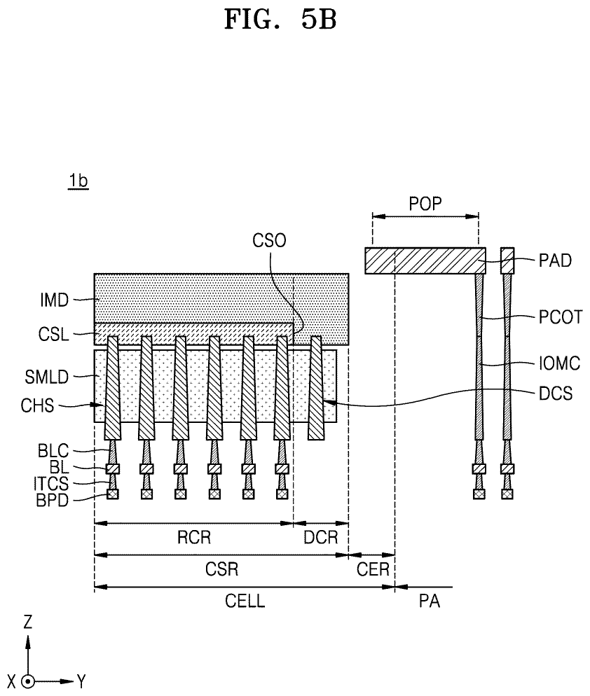

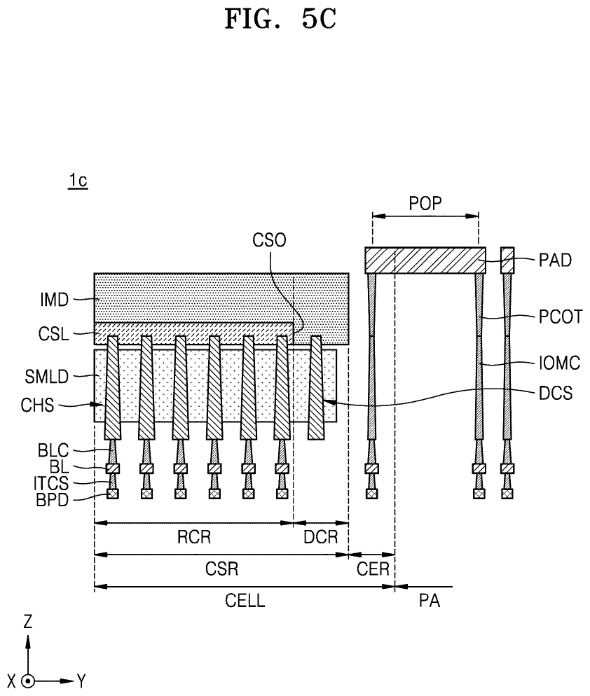

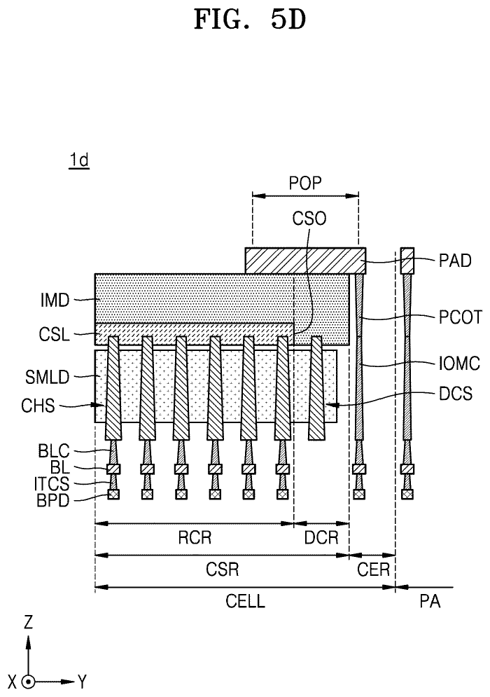

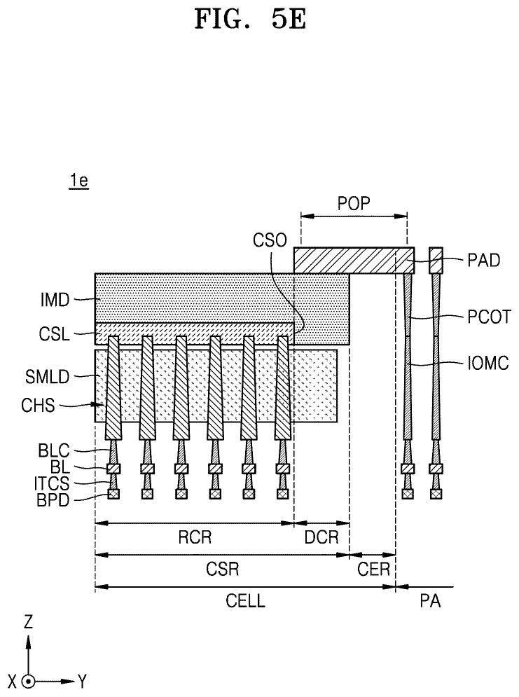

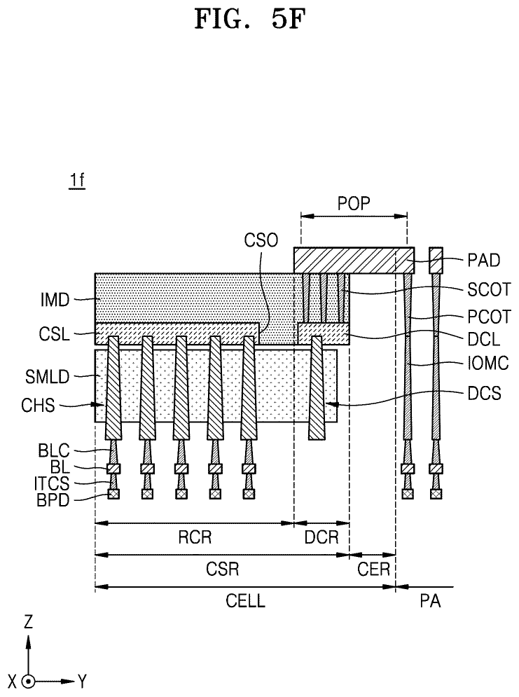

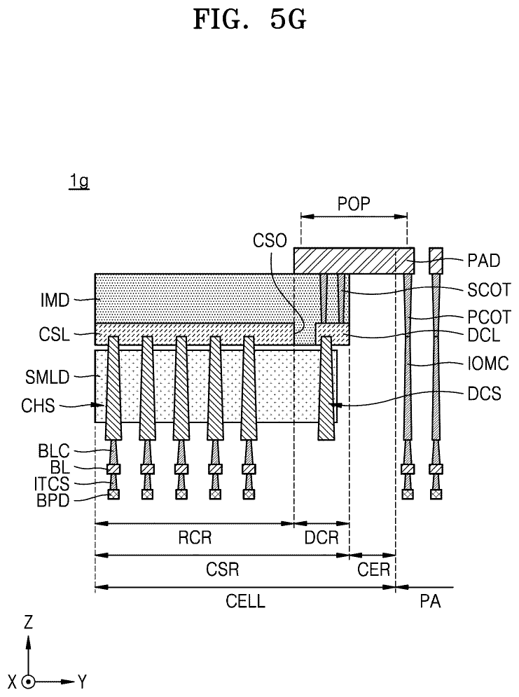

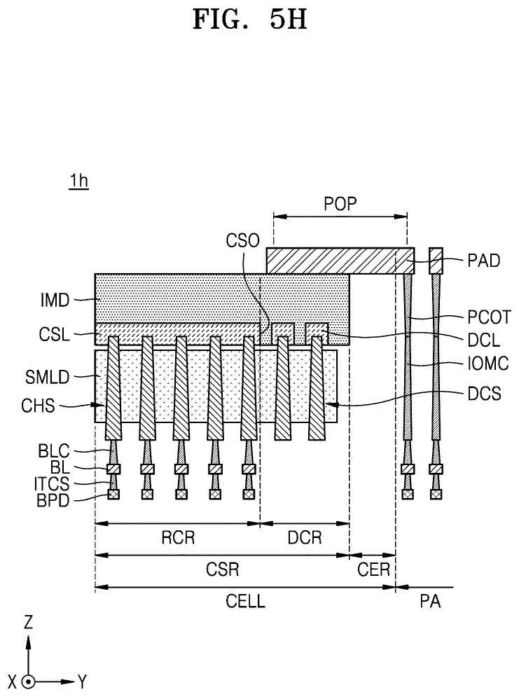

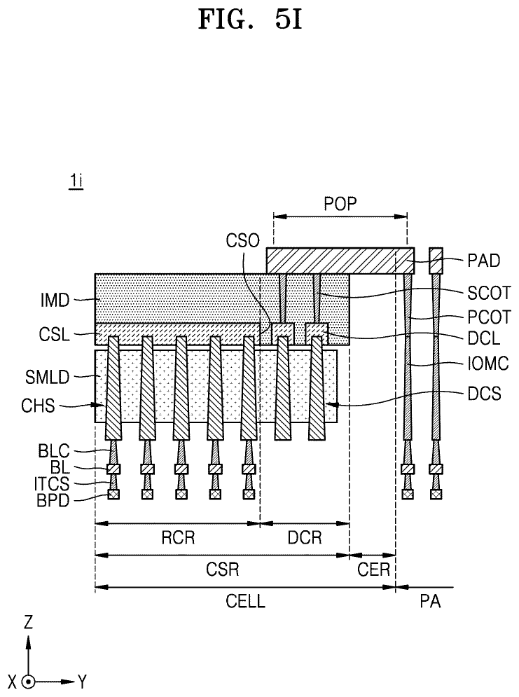

FIGS. 5A to 5I are cross-sectional views of a non-volatile memory device according to some embodiments.

Referring to FIG. 5A, a non-volatile memory device la includes a cell region CELL and a peripheral connection region PA adjacent to the cell region CELL. The peripheral connection region PA of FIG. 5A may be adjacent to the edge region ER of FIG. 4A. The cell region CELL includes the cell stack region CSR and the cell edge region CER arranged between the cell stack region CSR and the peripheral connection region PA. In the cell stack region CSR, a stack mold SMLD along with a plurality of cell channel structures CHS and a plurality of dummy structures DCS, which penetrate the stack mold SMLD, may be arranged. FIG. 5A illustrates that the non-volatile memory device la includes one dummy structure DCS; however, this is only for the convenience of explanation, and one or more embodiments are not limited thereto. For example, a plurality of dummy structures DCS may be arranged in columns in the first horizontal direction (the X direction). For example, a plurality of dummy structures DCS may be arranged in columns in the second horizontal direction (the Y direction). For example, a plurality of dummy structures DCS may be arranged in columns in each of the first horizontal direction (the X direction) and the second horizontal direction (the Y direction).

The cell stack region CSR includes a real cell region RCR and a dummy cell region DCR. In the real cell region RCR, the cell channel structures CHS may be arranged. In the dummy cell region DCR, no cell channel structure CHS may be arranged. In the dummy cell region DCR, the dummy structures DCS may be arranged. The dummy cell region DCR may be arranged along the edges of the cell stack region CSR to at least partially surround the real cell region RCR on a plane. For example, the dummy cell region DCR may be arranged between the real cell region RCR and the cell edge region CER.

In the cell region CELL, the stack mold SMLD and a common source line layer CSL on the stack mold SMLD may be arranged. The common source line layer CSL may correspond to the common source line CSL of FIG. 3. The stack mold SMLD and the common source line layer CSL may be arranged in the cell region CELL, but may not be arranged in the peripheral connection region PA. The stack mold SMLD may be arranged over the real cell region RCR and the dummy cell region DCR, but may not be arranged in the cell edge region CER. The cell channel structures CHS may extend in the vertical direction (the Z direction) to be connected to the common source line layer CSL by penetrating the stack mold SMLD.

The common source line layer CSL may be arranged in a portion of the cell stack region CSR and may not be arranged in other portions of the cell stack region CSR. The common source line layer CSL may have a common source opening CSO. The common source opening CSO may penetrate from an upper surface of the common source line layer CSL to a lower surface thereof. The common source line layer CSL may not be arranged in a portion of the cell stack region CSR that includes the common source opening CSO. For example, the common source line layer CSL may be on a portion of the stack mold SMLD and may not be on the remaining portions of the stack mold SMLD that include the common source opening CSO.

The common source opening CSO may be in the dummy cell region DCR. The common source opening CSO may be at the edge of the common source line layer CSL on a plane. The common source opening CSO may overlap the dummy cell region DCR on a plane. For example, the common source line layer CSL may only be in the real cell region RCR, but may not be in the dummy cell region DCR.

A base insulating layer IMD may be arranged on the common source line layer CSL. The base insulating layer IMD may fill the common source opening CSO and cover the common source line layer CSL. FIG. 5A illustrates that the base insulating layer IMD is arranged only on the stack mold SMLD in the cell stack region CSR; however, this is only for the convenience of explanation, and one or more embodiments are not limited thereto. For example, the base insulating layer IMD may also be in the cell edge region CER. For example, the base insulating layer IMD may be arranged near the stack mold SMLD to surround the stack mold SMLD in the cell stack region CSR and/or the cell edge region CER.

The pad pattern PAD may extend from the peripheral connection region PA to the cell region CELL to span the peripheral connection region PA and the cell region CELL. The pad pattern PAD may be exposed to the outside of the non-volatile memory device 1a through a pad opening POP. The pad pattern PAD may span the peripheral connection region PA, the cell edge region CER, and the dummy cell region DCR, but may not be in the real cell region RCR. For example, the pad pattern PAD may extend from the peripheral connection region PA to the dummy cell region DCR through the cell edge region CER. The pad pattern PAD may cover a portion of the base insulating layer IMD that is in the dummy cell region DCR.

The common source line layer CSL may not overlap the pad pattern PAD in the vertical direction (the Z direction). For example, the pad pattern PAD may overlap the common source opening CSO in the vertical direction (the Z direction) in the cell region CELL, but may not overlap the common source line layer CSL.

In the peripheral connection region PA, at least one through contact plug IOMC may be arranged under the pad pattern PAD. The pad pattern PAD may overlap at least one through contact plug IOMC in the vertical direction (the Z direction). In some embodiments, the pad pattern PAD may overlap the dummy structures DCS in the vertical direction (the Z direction), but may not overlap all of the cell channel structures CHS.

A pad connection via PCOT may be located between the pad pattern PAD and the through contact plug IOMC. The upper surface and the lower surface of the pad connection via PCOT may contact the lower surface of the pad pattern PAD and the upper surface of the through contact plug IOMC, respectively.

The cell channel structures CHS and at least one through contact plug IOMC may each be electrically connected to an upper bonding pad BPD. The cell channel structures CHS and at least one through contact plug IOMC may each be electrically connected to the peripheral circuit structure PS of FIG. 2 through the upper bonding pad BPD. The cell channel structures CHS and at least one through contact plug IOMC may each be electrically connected to the bit line BL. The cell channel structures CHS and at least one through contact plug IOMC may each be electrically connected to the bit line BL through a bit line contact BLC. The bit line BL may be electrically connected to the upper bonding pad BPD through an upper interconnect structure ITCS. For example, the bit line contact BLC, the bit line BL, and the upper interconnect structure ITCS may be sequentially arranged between the upper bonding pad BPD and each of the cell channel structures CHS and at least one through contact plug IOMC.

FIG. 5A illustrates the upper interconnect structure ITCS as one contact, but one or more embodiments are not limited thereto. For example, the upper interconnect structure ITCS may include one or more contacts and one or more wire layers. In some embodiments, each of the contact plug, the bit line contact BLC, and the through contact plug IOMC of the upper interconnect structure ITCS may have a tapered shape with a horizontal width decreasing from a lower portion to an upper portion. In some embodiments, the pad connection via PCOT may have a tapered shape with a horizontal width increasing from the lower portion of the pad connection via PCOT to the upper portion thereof.

The dummy structure DCS may not be electrically connected to the bit line BL. For example, the bit line contact BLC may be connected to the lower surface of each of the cell channel structures CHS and at least one through contact plug IOMC, but may not be connected to the lower surface of the dummy structure DCS.

The cell channel structures CHS may be electrically connected to the common source line layer CSL. The dummy structure DCS may not be electrically connected to the common source line layer CSL. The cell channel structures CHS may overlap the common source line layer CSL in the vertical direction (the Z direction), but may extend into the common source line layer CSL through the lower surface of the common source line layer CSL. The dummy structure DCS may not overlap the common source line layer CSL in the vertical direction (the Z direction). The dummy structure DCS may extend into the base insulating layer IMD through the lower surface of the base insulating layer IMD.

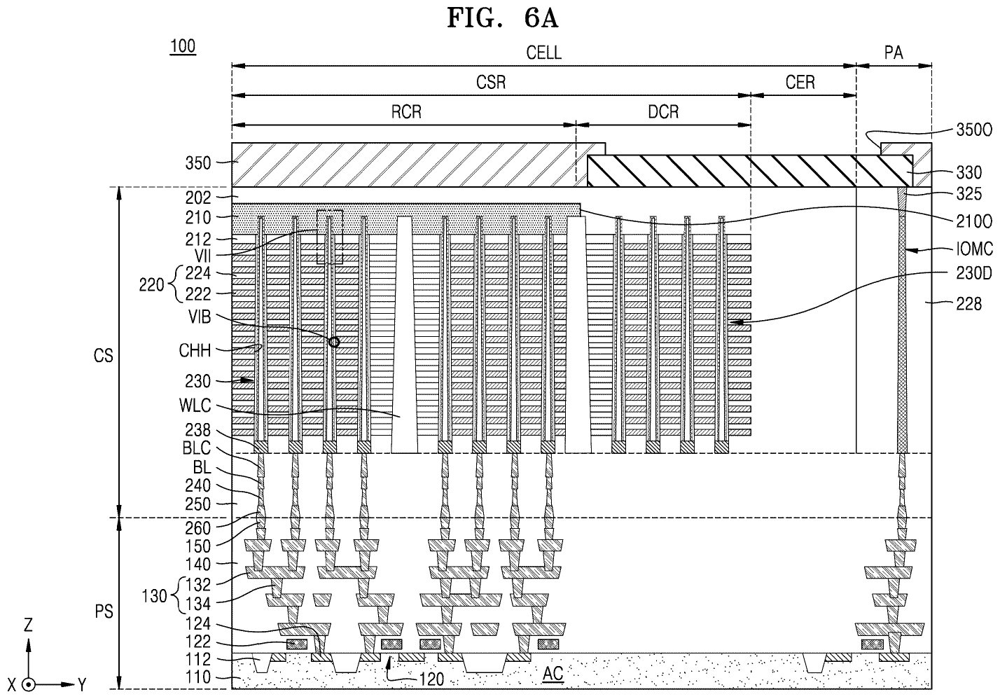

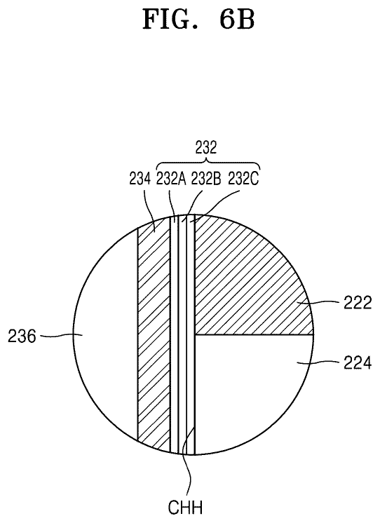

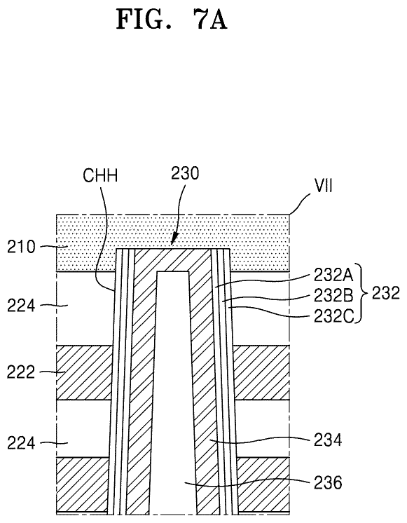

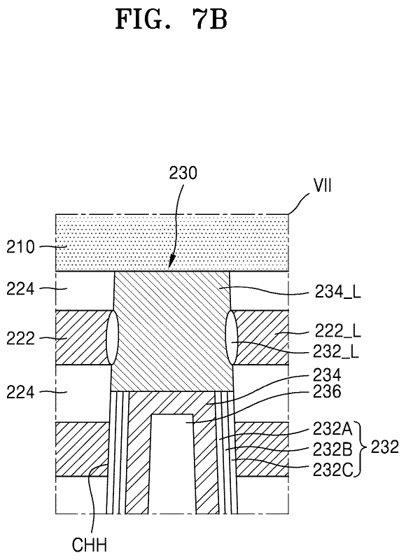

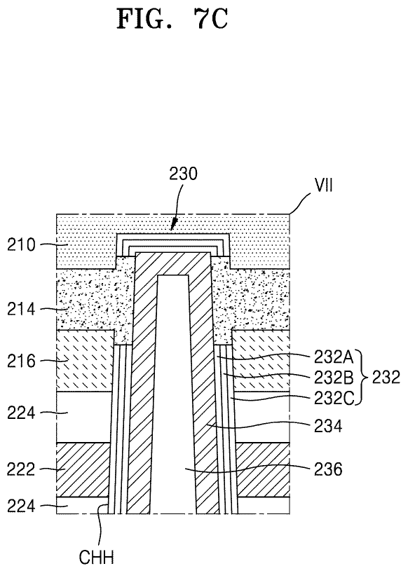

In some embodiments, the cell channel structure CHS and the dummy structure DCS may be at least partially formed together through the same manufacturing process. For example, the dummy structure DCS may have a structure that is the same as or substantially similar to that of the cell channel structure CHS. The structure of the cell channel structure CHS is described in detail with reference to FIGS. 6A to 7C.

In the non-volatile memory device la, the common source line layer CSL may not overlap the pad pattern PAD in the vertical direction (the Z direction). Also, in the non-volatile memory device la, a portion of the base insulating layer IMD filling the common source opening CSO is arranged between the through contact plug IOMC and the pad connection via PCOT and the common source line layer 210 such that the distance between the through contact plug IOMC and the pad connection via PCOT and the common source line layer 210 may increase. Therefore, a parasitic capacitance may be reduced between the pad pattern PAD and the common source line layer CSL as well as between the common source line layer CSL and the through contact plug IOMC electrically connected to the pad pattern PAD and the pad connection via PCOT, leading to the improvement in the operational reliability of the non-volatile memory device la.

Referring to FIG. 5B, the non-volatile memory device 1b includes the pad pattern PAD. The pad pattern PAD may extend from the peripheral connection region PA to the cell region CELL to span the peripheral connection region PA and the cell region CELL. The pad pattern PAD may be exposed to the outside of the non-volatile memory device 1b through the pad opening POP. The pad pattern PAD may span the peripheral connection region PA and the cell edge region CER, but may not be in the dummy cell region DCR and the real cell region RCR. For example, the pad pattern PAD may extend from the peripheral connection region PA to the cell edge region CER. FIG. 5B illustrates that the pad pattern PAD is spaced apart from the dummy cell region DCR in the second horizontal direction (the Y direction), but one or more embodiments are not limited thereto. For example, the pad pattern PAD may not overlap the dummy cell region DCR in the vertical direction (the Z direction), but may extend to the boundary of the dummy cell region DCR in the second horizontal direction (the Y direction).

Referring to FIG. 5C, a non-volatile memory device 1c includes the pad pattern PAD. The pad pattern PAD may extend from the peripheral connection region PA to the cell region CELL to span the peripheral connection region PA and the cell region CELL. The pad pattern PAD may be exposed to the outside of the non-volatile memory device 1c through the pad opening POP. The pad pattern PAD may span the peripheral connection region PA and the cell edge region CER, but may not be in the dummy cell region DCR and the real cell region RCR. For example, the pad pattern PAD may extend from the peripheral connection region PA to the cell edge region CER.

At least two through contact plugs IOMC may be arranged under the pad pattern PAD. The pad pattern PAD may overlap at least two through contact plugs IOMC in the vertical direction (the Z direction). A pad connection via PCOT may be located between the pad pattern PAD and each of the at least two through contact plugs IOMC. In some embodiments, at least one of the at least two through contact plugs IOMC electrically connected to the pad pattern PAD through the pad connection via PCOT may be located in the cell edge region CER. For example, at least one of the at least two through contact plugs IOMC electrically connected to the pad pattern PAD may be located in the cell edge region CER, and the other of the at least two through contact plugs IOMC may be located in the peripheral connection region PA.

Referring to FIG. 5D, a non-volatile memory device Id includes the pad pattern PAD. The pad pattern PAD may be exposed to the outside of the non-volatile memory device 1c through the pad opening POP. The pad pattern PAD may extend over the cell edge region CER, the dummy cell region DCR, and the real cell region RCR. In some embodiments, the pad pattern PAD may extend from the cell edge region CER to the real cell region RCR. In some embodiments, the pad pattern PAD may extend from the peripheral connection region PA to the cell region CELL, as illustrated in FIGS. 5A to 5C. For example, the pad pattern PAD may extend from the peripheral connection region PA to the real cell region RCR to span the peripheral connection region PA, the cell edge region CER, the dummy cell region DCR, and the real cell region RCR.

Referring to FIG. 5E, a non-volatile memory device le includes the pad pattern PAD. The pad pattern PAD may extend from the peripheral connection region PA to the cell region CELL to span the peripheral connection region PA and the cell region CELL. The pad pattern PAD may be exposed to the outside of the non-volatile memory device le through the pad opening POP. The pad pattern PAD may span the peripheral connection region PA, the cell edge region CER, and the dummy cell region DCR, but may not be in the real cell region RCR. For example, the pad pattern PAD may extend from the peripheral connection region PA to the dummy cell region DCR through the cell edge region CER. The pad pattern PAD may cover a portion of the base insulating layer IMD that is in the dummy cell region DCR.

The dummy structure DCS of FIG. 5A may not be arranged under the pad pattern PAD. In some embodiments, the non-volatile memory device le includes the dummy structure DCS included in the non-volatile memory device 1a of FIG. 5A, but the dummy structure DCS may not overlap the pad pattern PAD in the vertical direction (the Z direction). In some embodiments, the non-volatile memory device le may not include the dummy structure DCS included in the non-volatile memory device 1a of FIG. 5A.

Referring to FIG. 5F, a non-volatile memory device If includes a pad pattern PAD, at least one pad support via SCOT connected to the lower surface of the pad pattern PAD, and a dummy source line layer DCL.

The pad pattern PAD may extend from the peripheral connection region PA to the cell region CELL to span the peripheral connection region PA and the cell region CELL. The pad pattern PAD may be exposed to the outside of the non-volatile memory device If through the pad opening POP. The pad pattern PAD may span the peripheral connection region PA, the cell edge region CER, and the dummy cell region DCR, but may not be in the real cell region RCR. The pad pattern PAD may cover a portion of the base insulating layer IMD that is in the dummy cell region DCR.

The dummy source line layer DCL may be located in the dummy cell region DCR. The dummy source line layer DCL may be arranged in the common source opening CSO. The dummy source line layer DCL may be spaced apart from the common source line layer CSL in the second horizontal direction (the Y direction) with the common source opening CSO therebetween. The dummy source line layer DCL and the common source line layer CSL may be portions that are formed through the same manufacturing process and then separated from each other during the process of forming the common source opening CSO. The dummy source line layer DCL may be physically separated from the common source line layer CSL and electrically insulated therefrom. For example, the base insulating layer IMD may be arranged between the dummy source line layer DCL and the common source line layer CSL.

The dummy source line layer DCL may overlap the pad pattern PAD in the vertical direction (the Z direction). In some embodiments, all portions of the dummy source line layer DCL may overlap the pad pattern PAD in the vertical direction (the Z direction). The common source opening CSO may span the dummy cell region DCR and the real cell region RCR. At least one pad support via SCOT may be between the pad pattern PAD and the dummy source line layer DCL. The base insulating layer IMD may surround at least one pad support via SCOT. The pad support via SCOT may have a tapered shape with a horizontal width increasing from the lower portion of the pad support via SCOT to the upper portion thereof. In some embodiments, the pad connection via PCOT and the pad support via SCOT may be formed together through the same manufacturing process.

Referring to FIG. 5G, a non-volatile memory device 1g includes a pad pattern PAD, at least one pad support via SCOT connected to the lower surface of the pad pattern PAD, and a dummy source line layer DCL.

The dummy source line layer DCL may be located in the dummy cell region DCR. The dummy source line layer DCL may be spaced apart from the common source line layer CSL in the second horizontal direction (the Y direction) with the common source opening CSO therebetween. The common source opening CSO may be in the dummy cell region DCR, but may not be in the real cell region RCR.

Referring to FIG. 5H, a non-volatile memory device 1h includes a pad pattern PAD and a plurality of dummy source line layers DCL.

The pad pattern PAD may extend from the peripheral connection region PA to the cell region CELL to span the peripheral connection region PA and the cell region CELL. The pad pattern PAD may be exposed to the outside of the non-volatile memory device 1h through a pad opening POP. The pad pattern PAD may span the peripheral connection region PA, the cell edge region CER, and the dummy cell region DCR, but may not be in the real cell region RCR. The pad pattern PAD may cover a portion of the base insulating layer IMD that is in the dummy cell region DCR.

The dummy source line layers DCL may be spaced apart from each other in the dummy cell region DCR. The dummy source line layers DCL may be spaced apart from each other in horizontal directions (the X direction, the Y direction, and the X-Y direction) with the common source opening CSO therebetween. A portion of the common source opening CSO, which is between the common source line layer CSL and the dummy source line layer DCL that is closest to the common source line layer CSL, may communicate with a portion of the common source opening CSO located between the dummy source line layers DCL. Each dummy source line layer DCL may overlap at least one dummy structure DCS in the vertical direction (the Z direction). In some embodiments, at least one dummy structure DCS may extend into one of the dummy source line layers DCL through the lower surface of one of the dummy source line layers DCL. Each dummy source line layer DCL may overlap the pad pattern PAD in the vertical direction (the Z direction).

Referring to FIG. 5I, a non-volatile memory device 1i includes a pad pattern PAD, a plurality of pad support vias SCOT connected to the lower surface of the pad pattern PAD, and a plurality of dummy source line layers DCL. At least one pad support via SCOT may be between the pad pattern PAD and each dummy source line layer DCL.

FIGS. 6A and 6B are cross-sectional views of a non-volatile memory device according to some embodiments. In detail, FIG. 6B is an enlarged cross-sectional view showing an enlarged region VIB of FIG. 6A.

Referring to FIGS. 6A and 6B together, a non-volatile memory device 100 includes a peripheral circuit structure PS and a cell array structure CS that are bonded to each other in the vertical direction (the Z direction). The peripheral circuit structure PS and the cell array structure CS may be referred to as a first structure and a second structure or a lower structure and an upper structure, respectively. The peripheral circuit structure PS includes the peripheral circuit 30 described with reference to FIG. 1, and the cell array structure CS includes the memory cell array 20 described with reference to FIG. 1. The cell array structure 20 may include memory cells that are three-dimensionally arranged. The cell array structure CS includes the cell region CELL and the peripheral connection region PA. The cell region CELL includes the cell stack region CSR and the cell edge region CER. The cell stack region CSR includes a real cell region RCR and a dummy cell region DCR. In the peripheral connection region PA, components that electrically connect the cell region CELL to the peripheral circuit structure PS may be arranged.

The peripheral circuit structure PS includes a substrate 110 on which a peripheral circuit 120 is arranged, a lower interconnect structure 130 electrically connected to the peripheral circuit 120, a lower bonding pad 150 electrically connected to the peripheral circuit 120 through the lower interconnect structure 130, and a lower insulating structure 140 on the substrate 110 and the peripheral circuit 120.

The substrate 110 may include a semiconductor material, for example, a group IV semiconductor material, a group III-V semiconductor material, a group II-VI semiconductor material, or a group II-VI oxide semiconductor material. The group IV semiconductor material may include, for example, silicon (Si), germanium (Ge), or Si—Ge. The group III-V semiconductor material may include, for example, gallium arsenide (GaAs), indium phosphide (InP), gallium phosphide (GaP), indium arsenide (InAs), indium antimonide (InSb), or indium gallium arsenide (InGaAs). The group II-VI semiconductor material may include, for example, zinc telluride (ZnTe) or cadmium sulfide (Cds). The substrate 110 may be a bulk wafer or an epitaxial layer. The substrate 110 may be provided as a bulk wafer or an epitaxial layer. In some embodiments, the substrate 110 may include a silicon-on-insulator (SOI) substrate or a germanium-on-insulator (GeOI) substrate. An active area AC may be defined in the substrate 110 by a device isolation layer 112, and a plurality of peripheral circuits 120 may be formed in the active area AC. The peripheral circuits 120 include a peripheral circuit gate 122 and source/drain areas 124 on portions of the substrate 110 that are on both sides of the peripheral circuit gate 122.

The lower interconnect structure 130 includes a plurality of peripheral circuit wire layers 132 and a plurality of peripheral circuit contacts 134. The lower interconnect structure 130 may include a conductive material, for example, copper (Cu), aluminum (Al), tungsten (W), silver (Ag), gold (Au), or a combination thereof. The lower bonding pad 150 may be arranged on the lower interconnect structure 130 and electrically connected to the peripheral circuit 120 and/or the substrate 110 through the lower interconnect structure 130. The lower insulating structure 140 may surround the peripheral circuit 120, the lower interconnect structure 130, and the lower bonding pad 150 on the substrate 110. The lower bonding pad 150 may have an upper surface that is on the same plane as the upper surface of the lower insulating structure 140.

In some embodiments, the lower insulating structure 140 may include an insulating material including silicon oxide, silicon nitride, a low-k dielectric material, or a combination thereof. The low-k dielectric material may have a lower dielectric constant than silicon oxide and include, for example, phosphosilicate glass (PSG), borophosphosilicate glass (BPSG), fluorosilicate glass (FSG), organosilicate glass (OSG), spin-on-glass (SOG), spin-on-polymer, or a combination thereof. In some embodiments, the lower insulating structure 140 may include an ultra-low-k (ULK) layer having an ultra-low dielectric constant K of about 2.2 to about 2.4. The ULK layer may include SiOC or SiCOH. The lower bonding pad 150 may include a conductive material that may include Cu, Au, Ag, Al, W, titanium (Ti), tantalum (Ta), or a combination thereof.

The cell array structure CS includes the common source line layer 210, the cell stack 220 under the common source line layer 210, the upper interconnect structure 240 electrically connected to the cell stack 220, the upper bonding pad 260 electrically connected to the upper interconnect structure 240, and the upper insulating structure 250 arranged under the cell stack 220, covering the cell stack 220, and surrounding the bit line contact BLC, the bit line BL, the upper interconnect structure 240, and the upper bonding pad 260. The upper bonding pad 260 may have a lower surface that is located on the same plane as the lower surface of the upper insulating structure 250.

The non-volatile memory device 100 may further include a base insulating layer 202 covering the common source line layer 210 on the cell stack 220, a pad pattern 330 arranged on the base insulating layer 202, and a protective insulating layer 350 covering a portion of the pad pattern 330 on the base insulating layer 202. The protective insulating layer 350 includes a pad opening 3500 that does not cover and exposes the upper surface of the remaining portion of the pad pattern 330. The base insulating layer 202 may include an insulating material that includes silicon oxide, silicon nitride, a low-k dielectric material, or a combination thereof. The pad pattern 330 may extend from the peripheral connection region PA to the dummy cell region DCR to span the peripheral connection region PA, the cell edge region CER, and the dummy cell region DCR.

The common source line layer 210 may be the common source line layer CSL illustrated in FIGS. 5A to 5I. The base insulating layer 202, the cell stack 220, the upper interconnect structure 240, and the upper bonding pad 260 may be the base insulating layer IMD, the stack mold SMLD, the upper interconnect structure ITCS, and the upper bonding pad BPD, respectively, of FIGS. 5A to 5I.

FIG. 6A illustrates that the upper interconnect structure 240 only includes a plurality of contacts; however, this is only an example, and one or more embodiments are not limited thereto. For example, similar to the lower interconnect structure 130 including the peripheral circuit wire layers 132 and the peripheral circuit contacts 134, the upper interconnect structure 240 may include a plurality of wire layers and a plurality of contacts. Each of the upper interconnect structure 240 and the upper insulating structure 250 may include a material that is the same as or similar to each of the lower interconnect structure 130 and the lower insulating structure 140.

The upper insulating structure 250 may contact and be bonded to the lower bonding pad 150 that contacts the lower insulating structure 140 and corresponds to the upper bonding pad 260, and the cell array structure CS may be bonded to the peripheral circuit structure PS. For example, the peripheral circuit structure PS may be bonded to the cell array structure CS through metal-oxide hybrid bonding, and thus, the upper interconnect structure 240 included in the cell array structure CS may be electrically connected to the peripheral circuit 120 included in the peripheral circuit structure PS.

The cell stack 220 includes a plurality of gate electrodes 222 and a plurality of insulating layers 224 that are alternately arranged under the common source line layer 210. The gate electrodes 222 may include conductive materials. The insulating layers 224 may include insulating materials.

A buffer insulating layer 212 may be between the common source line layer 210 and the cell stack 220. For example, the buffer insulating layer 212 may be arranged between the common source line layer 210 and an uppermost gate electrode 222 among the cell stack 220. The buffer insulating layer 212 may include an insulating material, for example, oxide. The buffer insulating layer 212 may have a thickness of several tens to several hundreds of nm. The thickness of the gate electrode 222 may be equal to or greater than the thickness of the insulating layer 224. For example, the gate electrode 222 may have a thickness of about 10 nm to about 20 nm, and the insulating layer 224 may have a thickness of about 10 nm to about 15 nm.

In the real cell region RCR, a plurality of cell channel structures 230 vertically extending by penetrating the cell stack 220 including the gate electrodes 222 and the insulating layers 224 may be arranged. Along each of the cell channel structures 230, the memory cell string (MS of FIG. 3) including a plurality of memory cells may be formed. Each cell channel structure 230 may penetrate the cell stack 220 and the buffer insulating layer 212 and extend into the common source line layer 210 in the vertical direction (the Z direction). For example, part of an upper portion of each cell channel structure 230 may protrude from an upper surface of the buffer insulating layer 212 in the vertical direction (the Z direction) and may be arranged in the common source line layer 210. The cell channel structure 230 may be the cell channel structure CHS of FIGS. 5A to 5I.

In some embodiments, the non-volatile memory device 100 may further include a word line cut area WLC penetrating the cell stack 220. The word line cut area WLC may penetrate the cell stack 220 and extend into the common source line layer 210. The word line cut area WLC may be spaced apart from the cell channel structures 230. In some embodiments, the word line cut area WLC may extend in the first horizontal direction (the X direction) along the gap between the cell channel structures 230 that are adjacent to each other in the second horizontal direction (the Y direction). The word line cut area WLC may include an oxide layer, a nitride layer, or a combination thereof.

The common source line layer 210 may function as a source area where a current is supplied to the memory cells formed on the cell array structure CS. The common source line layer 210 may correspond to the common source line CSL of FIG. 3. The common source line layer 210 may include a semiconductor material, such as a group IV semiconductor material, a group III-V semiconductor material, or a group II-VI semiconductor material. For example, the common source line layer 210 may include at least one of Si, Ge, SiGe, GaAs, InGaAs, AlGaAs, and a combination thereof. In addition, the common source line layer 210 may include a semiconductor doped with n-type impurities. Also, the common source line layer 210 may have a crystalline structure including at least one selected from among a single-crystal structure, an amorphous structure, and a polycrystalline structure. In some embodiments, the common source line layer 210 may include a semiconductor material that does not contain carbon. For example, the common source line layer 210 may include polysilicon. In some embodiments, the common source line layer 210 may include polysilicon that does not contain carbon. In some embodiments, the common source line layer 210 may include polysilicon doped with n-type impurities.

The common source line layer 210 may be arranged such that the cell channel structure 230 may penetrate the gate electrodes 222 and the insulating layers 224 and be in contact with the common source line layer 210. The common source line layer 210 may extend along the lower surface of the base insulating layer 202 and surround a portion of an upper portion of each cell channel structure 230.

In some embodiments, the gate electrodes 222 may correspond to at least one ground selection line GSL, the word line WL (WL: WL1, WL2, . . . , WLn−1, and WLn), and at least one string selection line SSL that form the memory cell string MS of FIG. 3. For example, the gate electrode 222, which is closest to the common source line layer 210, may function as the ground selection line GSL, at least two gate electrodes 222, which are farthest from the common source line layer 210, may function as the string selection lines SSL, and the other gate electrodes 222 may function as the word lines WL. Accordingly, the ground selection transistor GST, the string selection transistor SST, and the memory cell string MS between the ground selection transistor GST and the string selection transistor SST, as illustrated in FIG. 3, may be provided, wherein the memory cell transistors MC1, MC2, . . . , MCn−1, and MCn may be connected to the memory cell string MS in series.

In some embodiments, at least one of the gate electrodes 222 may function as a dummy word line. For example, at least one gate electrode 222 functioning as an additional dummy word line may be arranged between the common source line layer 210 and the gate electrode 222 functioning as the ground selection line GSL, at least one gate electrode 222 functioning as an additional dummy word line may be arranged between the gate electrode 222 functioning as the ground selection line GSL and the gate electrode 222 functioning as the word line WL, or at least one gate electrode 222 functioning as an additional dummy word line may be arranged between the gate electrode 222 functioning as the word line WL and the gate electrode 222 functioning as the string selection line SSL.

The cell channel structures 230 may be arranged apart from each other at certain intervals along the first horizontal direction (the X direction), the second horizontal direction (the Y direction), and a third horizontal direction (for example, a direction diagonal to the first horizontal direction (the X direction) and the second horizontal direction (the Y direction)). The cell channel structures 230 may be arranged in a zigzag shape or a staggered shape. Each cell channel structure 230 includes a conductive plug 238. The conductive plug 238 may be arranged on an end portion of each cell channel structure 230 that is opposite to the conductive plug 238 with respect to the common source line layer 210.

The cell channel structures 230 may be arranged in a plurality of channel holes CHH in the real cell region RCR. The channel holes CHH may penetrate the buffer insulating layer 212 and the cell stack 220 including the gate electrodes 222 and the insulating layers 224 and may extend into the common source line layer 210. The channel holes CHH may be defined by the gate electrodes 222 and the insulating layers 224 in the cell stack 220 and by the common source line layer 210.

Each cell channel structure 230 includes a gate insulating layer 232, a channel layer 234, a buried insulating layer 236, and a conductive plug 238. The gate insulating layer 232 and the channel layer 234 may be sequentially arranged on an inner sidewall of the channel hole CHH. For example, the gate insulating layer 232 may conformally cover the cell stack 220 including the insulating layers 224 and the inner sidewall of the channel hole CHH penetrating the buffer insulating layer 212, and the channel layer 234 may conformally cover the inner side wall and the ceiling surface of the channel hole CHH. The channel layer 234 may cover the inner sidewall and the ceiling surface of the channel hole CHH extending to the common source line layer 210 to be in contact with the common source line layer 210. The gate insulating layer 232 may not extend into the common source line layer 210. For example, the uppermost portion of the gate insulating layer 232 may contact the lower surface of the common source line layer 210. The channel layer 234 may extend into the common source line layer 210 along the inner sidewall of the channel hole CHH extending into the common source line layer 210. For example, the uppermost portion of the channel layer 234 may be at a higher vertical level than the lower surface of the common source line layer 210. Here, the lower surface of the common source line layer 210 refers to the lowermost surface of the common source line layer 210 except the inner sidewall and the ceiling surface of a portion of the channel hole CHH extending into the common source line layer 210.

A buried insulating layer 236 may be arranged on the channel layer 234 to fill the remaining space of the channel hole CHH. On a lower portion of the channel hole CHH, the conductive plug 238 contacting the channel layer 234 and blocking the entrance of the channel hole CHH may be arranged. In some embodiments, the buried insulating layer 236 may be omitted, and the channel layer 234 may be formed in a pillar shape that fills the remaining space of the channel hole CHH.

The gate electrode 222 may include metal, such as, W, Ni, Co, or Ta, conductive metal nitride, such as titanium nitride, tantalum nitride, or tungsten nitride, metal silicide, such as tungsten silicide, nickel silicide, cobalt silicide, or tantalum silicide, doped polysilicon, or a combination thereof. In some embodiments, a dielectric liner may be arranged between the gate electrode 222 and the insulating layer 224 and may include a high-k dielectric material, such as aluminum oxide.

The gate insulating layer 232 may have a structure in which a tunneling dielectric layer 232A, a charge storage layer 232B, and a blocking dielectric layer 232C are sequentially arranged on an outer sidewall of the channel layer 234. Relative thicknesses of the tunneling dielectric layer 232A, the charge storage layer 232B, and the blocking dielectric layer 232C that form the gate insulating layer 232 are not limited to those illustrated in FIG. 6B and may vary.

The tunneling dielectric layer 232A may include silicon oxide, hafnium oxide, aluminum oxide, zirconium oxide, tantalum oxide, or the like. The charge storage layer 232B may be a region, in which electrons passing through the tunneling dielectric layer 232A from the channel layer 234 may be stored, and may include silicon nitride, boron nitride, silicon boron nitride, or polysilicon doped with impurities. The blocking dielectric layer 232C may include silicon oxide, silicon nitride, or metal oxide having greater permittivity than that of silicon oxide. The above metal oxide may include hafnium oxide, aluminum oxide, zirconium oxide, tantalum oxide, or a combination thereof.

The bit lines BL may be spaced apart from each other in the first horizontal direction (the X direction) and extend, but one or more embodiments are not limited thereto. For example, the bit lines BL may be spaced apart from each other in the second horizontal direction (the Y direction) and extend. The bit line BL may be electrically connected to the cell channel structure 230 through the bit line contact BLC. The bit line contact BLC may be connected to the conductive plug 238.

The dummy structures 230D may be arranged in the channel holes CHH in the dummy cell region DCR. The dummy structure 230D may be formed to prevent the leaning or bending of the gate electrodes 222 during the manufacturing processes of the non-volatile memory device 100 and to secure structural stability. In some embodiments, the dummy structure 230D may have a structure and a shape that are substantially the same as or similar to those of the cell channel structure 230. When the dummy structure 230D has a structure and a shape that are the same as or similar to those of the cell channel structure 230, the cell channel structure 230 may be referred to as a real cell channel structure and the dummy structure 230D may be referred to as a dummy cell channel structure. For example, the dummy structure 230D includes the gate insulating layer 232, the channel layer 234, and the buried insulating layer 236 but may not include the conductive plug 238. In some embodiments, the cell channel structure 230 may have a structure and a shape that are different from those of the dummy structure 230D. The dummy structure 230D may be the dummy structure DCS of FIGS. 5A to 5I.

In the peripheral connection region PA, a filling insulating layer 228 filling portions corresponding to the cell stack 220 may be arranged. The upper insulating structure 250 may cover the cell stack 220 and the filling insulating layer 228. In some embodiments, the upper insulating structure 250 may include a plurality of insulating layers, and each insulating layer may be arranged to cover the bit line contact BLC, the bit line BL, and the upper interconnect structure 240. In the peripheral connection region PA, the through contact plug IOMC that penetrates the filling insulating layer 228 and is electrically connected to the peripheral circuit 120 through the upper interconnect structure 240 and the lower interconnect structure 130 may be arranged. The through contact plug IOMC may extend into the base insulating layer 202.

In some embodiments, the cell channel structures 230, the dummy structures 230D, and the through contact plug IOMC may each extend from the common source line layer 210 and the base insulating layer 202 to the peripheral circuit structure PS in the vertical direction (the Z direction) and have a tapered shape with an increasing horizontal width.

The common source line layer 210 may have the common source opening 2100. The common source opening 2100 may be the common source opening CSO of FIGS. 5A to 5I. The common source opening 2100 may not be in the peripheral connection region PA and the cell edge region CER, but may only be in the cell stack region CSR. The pad pattern 330 may extend from the peripheral connection region PA onto the common source opening 2100. In some embodiments, the common source opening 2100 may be in the dummy cell region DCR but may not be in the real cell region RCR. The base insulating layer 202 may fill the common source opening 2100. The common source line layer 210 may not overlap the pad pattern 330 in the vertical direction (the Z direction). For example, the pad pattern 330 may overlap the common source opening CSO in the vertical direction (the Z direction) in the cell stack region CSR, but may not overlap the common source line layer CSL.

The dummy structures 230D may penetrate the cell stack 220 and extend into the base insulating layer 202 filling the common source opening 2100. The dummy structure 230D may not overlap the common source line layer 210 in the vertical direction (the Z direction). At least some of the dummy structures 230D may overlap the pad pattern 330 in the vertical direction (the Z direction).

A pad connection via 325 may be located between the pad pattern 330 and the through contact plug IOMC. The upper surface and the lower surface of the pad connection via 325 may contact the lower surface of the pad pattern 330 and the upper surface of the through contact plug IOMC. The pad connection via 325 may penetrate the filling insulating layer 228. The pad connection via 325 may be the pad connection via PCOT of FIGS. 5A to 5I.

The cell channel structures 230 and the through contact plug IOMC may each be electrically connected to the upper bonding pad 260. The cell channel structures 230 and the through contact plug IOMC may each be electrically connected to the peripheral circuit 120 of the peripheral circuit structure PS through the upper bonding pad 260. The cell channel structures 230 and the through contact plug IOMC may each be electrically connected to the bit line BL. The cell channel structures 230 and the through contact plug IOMC may each be electrically connected to the bit line BL through the bit line contact BLC. The bit line BL may be electrically connected to the upper bonding pad 260 through the upper interconnect structure 240. For example, the bit line contact BLC, the bit line BL, and the upper interconnect structure 240 may be sequentially arranged between the upper bonding pad 260 and each of the cell channel structures 230 and the through contact plug IOMC.

The dummy structure 230D may not be electrically connected to the upper bonding pad BPD. The dummy structure 230D may not be electrically connected to the bit line BL. For example, the bit line contact BLC may be connected to the lower surface of each of the cell channel structures 230 and the through contact plug IOMC, but may not be connected to the lower surface of the dummy structure 230D. In some embodiments, the lower surface of the dummy structure 230D may be covered by the upper insulating structure 250.

FIGS. 7A to 7C are enlarged cross-sectional views of a cell channel structure according to some embodiments. FIGS. 7A to 7C are enlarged views illustrating a portion corresponding to a region VII of FIG. 6A.

Referring to FIG. 6 and FIG. 7A together, each cell channel structure 230 may be arranged in the channel hole CHH in the real cell region RCR. Each cell channel structure 230 includes a gate insulating layer 232, a channel layer 234, a buried insulating layer 236, and a conductive plug 238. The gate insulating layer 232 and the channel layer 234 may be sequentially arranged on the sidewall of the channel hole CHH. For example, the gate insulating layer 232 may be conformally arranged on the sidewall of the channel hole CHH, and the channel layer 234 may be conformally arranged on the sidewall and the bottom portion of the channel hole CHH. The channel layer 234 may be in contact with the upper surface of the common source line layer 210 on the bottom portion of the channel hole CHH. The buried insulating layer 236 may be arranged on the channel layer 234 to fill the remaining space of the channel hole CHH. On an upper portion of the channel hole CHH, the conductive plug 238 contacting the channel layer 234 and blocking the entrance of the channel hole CHH may be arranged. In some embodiments, the buried insulating layer 236 may be omitted, and the channel layer 234 may be formed in a pillar shape that fills the remaining space of the channel hole CHH.

The gate insulating layer 232 may have a structure in which the tunneling dielectric layer 232A, the charge storage layer 232B, and the blocking dielectric layer 232C are sequentially arranged on the outer sidewall of the channel layer 234.

Referring to FIG. 7B, the cell channel structure 230 further includes a contact semiconductor layer 234_L and a lower insulating layer 232_L arranged on the bottom portion of the channel hole CHH (here, a first end portion of the channel hole CHH that is arranged adjacent to the common source line layer 210 is referred to as the bottom portion). The channel layer 234 may not be in direct contact with the common source line layer 210 and may be electrically connected to the common source line layer 210 through the contact semiconductor layer 234_L. In some embodiments, the contact semiconductor layer 234_L may include a silicon layer that is formed through a selective epitaxy growth (SEG) process by taking the common source line layer 210 on the bottom portion of the channel hole CHH as a seed layer.

The lower insulating layer 232_L may be arranged between the contact semiconductor layer 234_L and an uppermost gate electrode 222_L that is closest to the common source line layer 210. In some embodiments, the lower insulating layer 232_L may include silicon oxide and may be formed, for example, by performing an oxidation process on a portion of the sidewall of the contact semiconductor layer 234_L.

Referring to FIG. 7C, the cell channel structure 230 may be electrically connected to a horizontal semiconductor layer 214 through the sidewall of the channel layer 234 instead of being electrically connected to the common source line layer 210. For example, the horizontal semiconductor layer 214 and the support layer 216 may be sequentially stacked on the lower surface of the common source line layer 210, and the insulating layer 224 and the gate electrode 222 may be arranged under the support layer 216.

In some embodiments, the horizontal semiconductor layer 214 may include polysilicon doped with impurities or polysilicon not being doped with impurities. The horizontal semiconductor layer 214 may function as a portion of a common source area connecting the common source line layer 210 to the channel layer 234. For example, the support layer 216 may include polysilicon that is doped or not doped with impurities. The support layer 216 may function as a support layer to prevent the mold stack from collapsing or falling during the process of removing a sacrificial material layer (not shown) used to form the horizontal semiconductor layer 214.

The gate insulating layer 232 may be arranged on the inner wall and the bottom portion of the channel hole CHH. The bottom surface of the channel layer 234 may be arranged on the gate insulating layer 232 and may not directly contact the common source line layer 210, and the sidewall of the bottom portion of the channel layer 234 may be surrounded by the horizontal semiconductor layer 214.

FIGS. 7A to 7C schematically show a representative structure of the cell channel structure 230 that may be adopted in some embodiments, and it should be understood in some embodiments that the cell channel structure 230 may have different structures from those described with reference to FIGS. 7A to 7C.

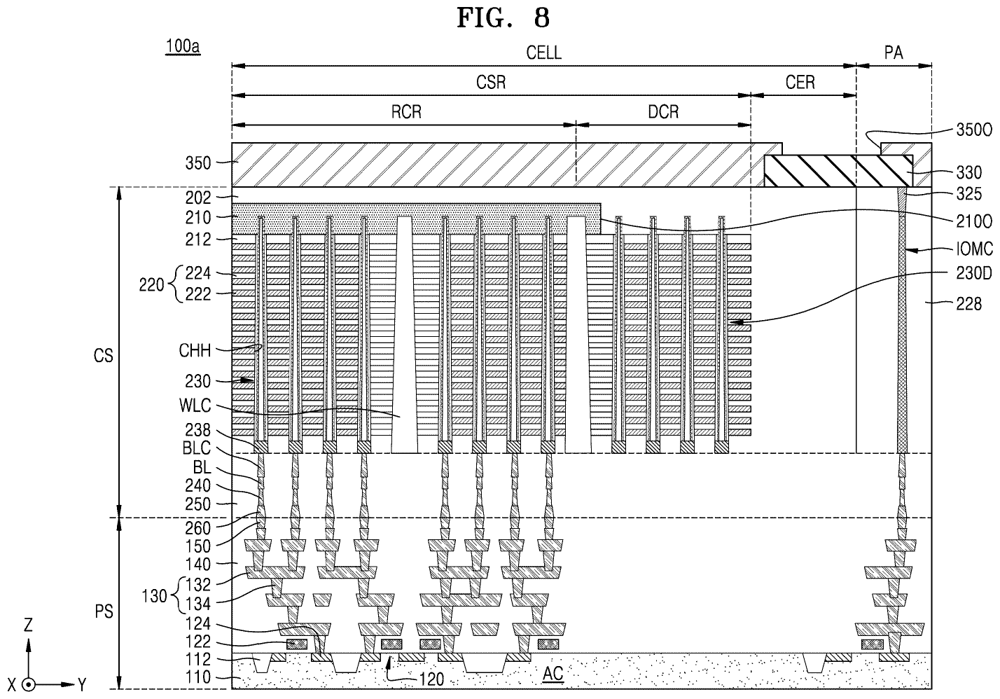

FIGS. 8 to 12 are cross-sectional views of a non-volatile memory device according to some embodiments.

Referring to FIG. 8, a non-volatile memory device 100a includes a peripheral circuit structure PS and a cell array structure CS that are bonded to each other in the vertical direction (the Z direction).

The pad pattern 230 may extend from the peripheral connection region PA to the cell region CELL to span the peripheral connection region PA and the cell edge region CER. The pad pattern 330 may be in the peripheral connection region PA and the cell edge region CER, but may not be in the dummy cell region DCR and the real cell region RCR. FIG. 8 illustrates that the pad pattern 330 is spaced apart from the dummy cell region DCR in the second horizontal direction (the Y direction), but one or more embodiments are not limited thereto. For example, the pad pattern 330 may not overlap the dummy cell region DCR in the vertical direction (the Z direction), but may extend to the boundary of the dummy cell region DCR in the second horizontal direction (the Y direction).

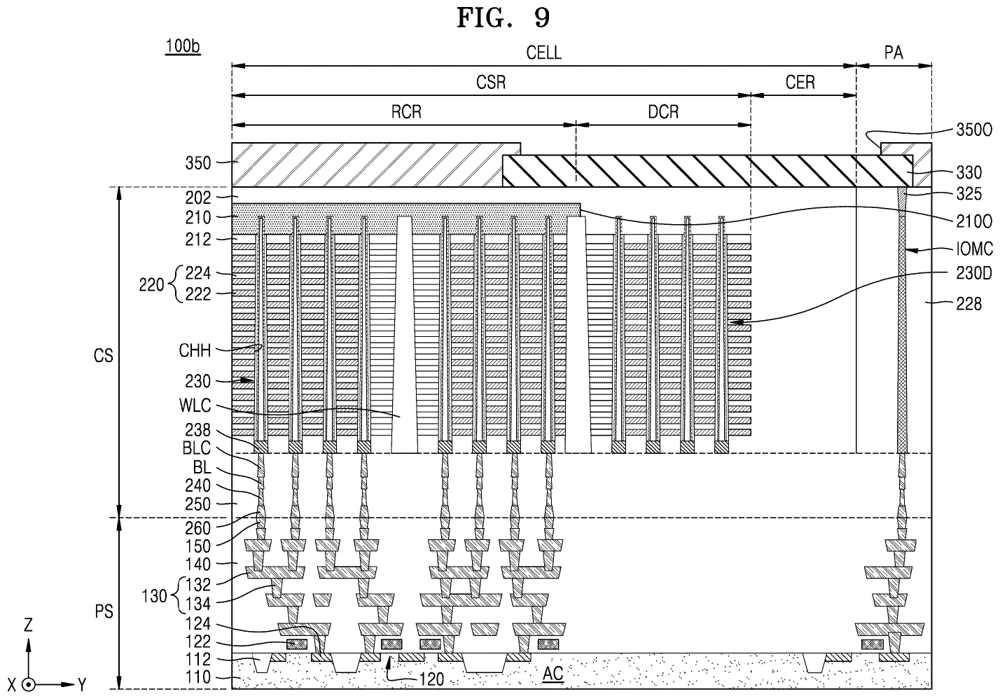

Referring to FIG. 9, a non-volatile memory device 100b includes a peripheral circuit structure PS and a cell array structure CS that are bonded to each other in the vertical direction (the Z direction).

The pad pattern 330 may span the peripheral connection region PA, the cell edge region CER, the dummy cell region DCR, and the real cell region RCR. In some embodiments, the pad pattern 330 may extend from the peripheral connection region PA to the real cell region RCR. In some embodiments, similar to the pad pattern PAD of FIG. 5D, the pad pattern 330 may extend from the cell edge region CER to the real cell region RCR.

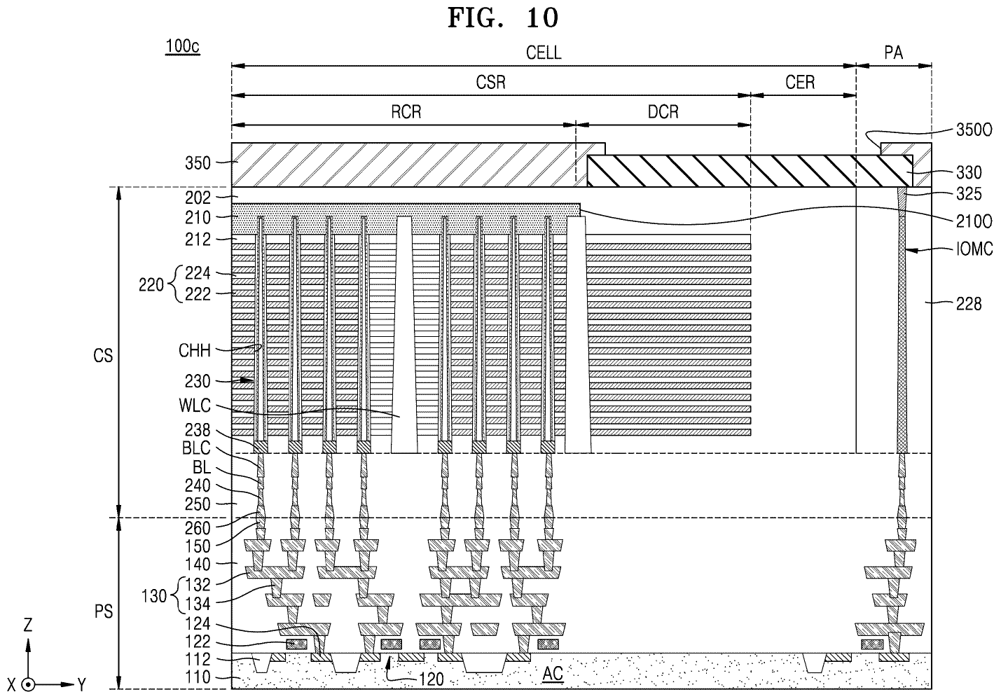

Referring to FIG. 10, a non-volatile memory device 100c includes a peripheral circuit structure PS and a cell array structure CS that are bonded to each other in the vertical direction (the Z direction).

The pad pattern 330 may extend from the peripheral connection region PA to the cell region CELL to span the peripheral connection region PA and the cell region CELL. The pad pattern 330 may span the peripheral connection region PA, the cell edge region CER, and the dummy cell region DCR, but may not be in the real cell region RCR. The pad pattern 330 may cover a portion of the base insulating layer 202 that is in the dummy cell region DCR.

The dummy structure 230D of FIG. 6A may not be arranged under the pad pattern 330. In some embodiments, the non-volatile memory device 100c includes the dummy structure 230D included in the non-volatile memory device 100 of FIG. 6A, but the dummy structure 230D may not overlap the pad pattern 330 in the vertical direction (the Z direction). In some embodiments, the non-volatile memory device 100c may not include the dummy structure 230D included in the non-volatile memory device 100 of FIG. 6A.

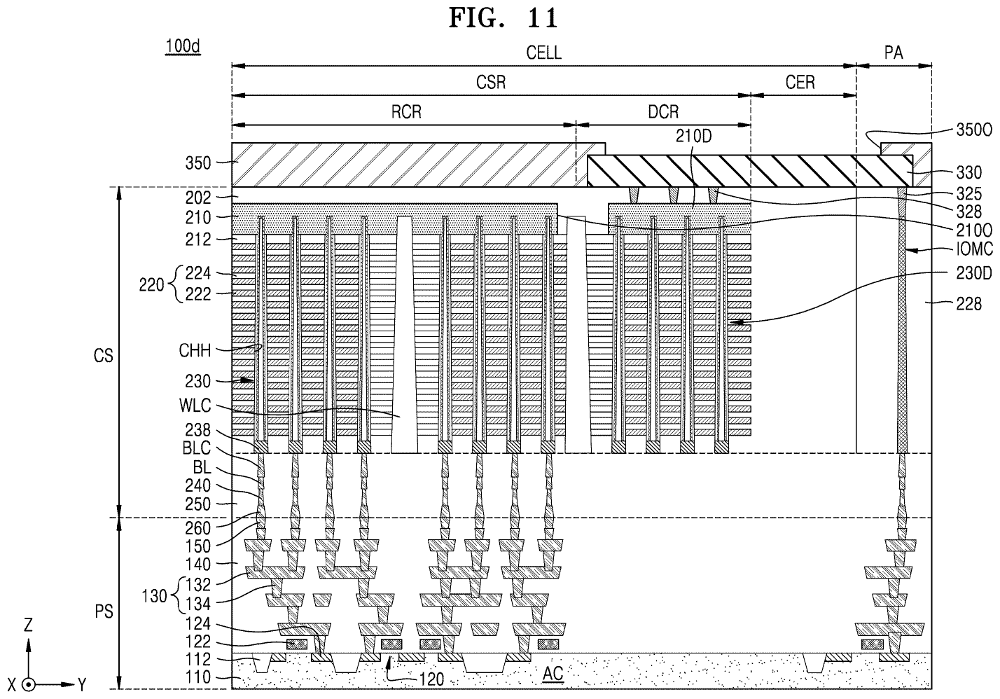

Referring to FIG. 11, a non-volatile memory device 100d includes a peripheral circuit structure PS and a cell array structure CS that are bonded to each other in the vertical direction (the Z direction).

Unlike the non-volatile memory device 100 of FIG. 6A, the non-volatile memory device 100d includes at least one pad support via 328 connected to the lower surface of the pad pattern 330 and the dummy source line layer 210D. The pad support via 328 and the dummy source line layer 210D may correspond to the pad support via SCOT and the dummy source line layer DCL of FIG. 5F.

The dummy source line layer 210D may be located in the dummy cell region DCR. The dummy source line layer 210D may be spaced apart from the common source line layer 210 in the second horizontal direction (the Y direction) with the common source opening 2100 therebetween. The dummy source line layer 210D may be physically separated from the common source line layer 210 and electrically insulated therefrom. For example, the base insulating layer 202 may be arranged between the dummy source line layer 210D and the common source line layer 210.

The dummy source line layer 210D may overlap the pad pattern 330 in the vertical direction (the Z direction). The common source opening 2100 may span the dummy cell region DCR and the real cell region RCR, but one or more embodiments are not limited thereto. For example, similar to the common source opening CSO of FIG. 5G, the common source opening 2100 may be in the dummy cell region DCR, but may not be in the real cell region RCR. At least one pad support via 328 may be between the pad pattern 330 and the dummy source line layer 210D. The base insulating layer 202 may surround at least one pad support via 328. The pad support via 328 may have a tapered shape with a horizontal width increasing from the lower portion of the pad support via 328 to the upper portion thereof. In some embodiments, the pad connection via 328 and the pad support via 325 may be formed together through the same manufacturing process.

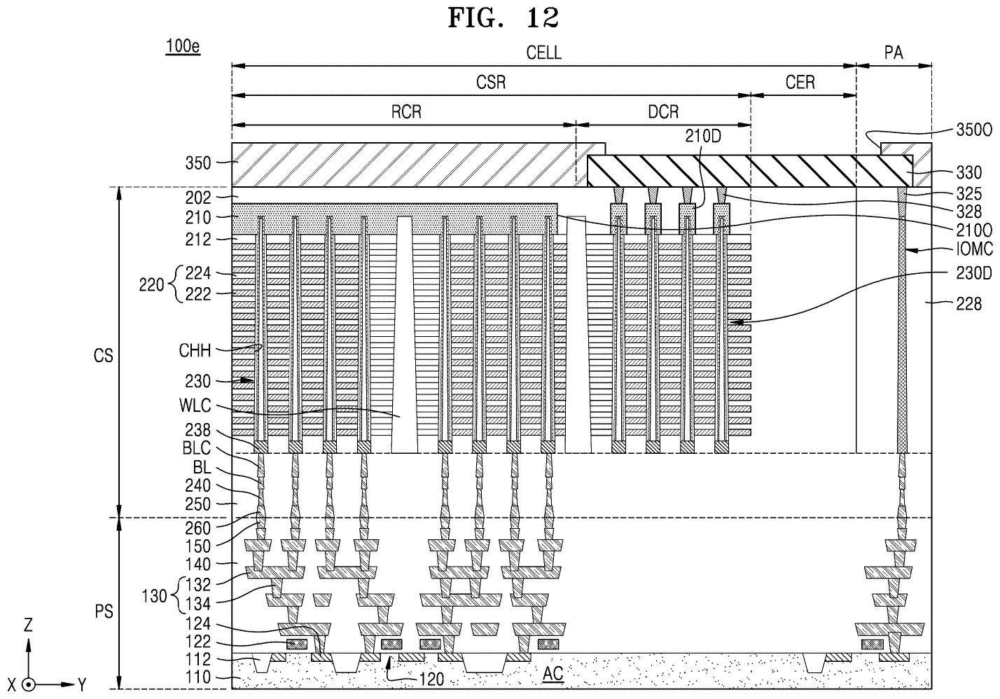

Referring to FIG. 12, a non-volatile memory device 100e includes a peripheral circuit structure PS and a cell array structure CS that are bonded to each other in the vertical direction (the Z direction).

Unlike the non-volatile memory device 100 of FIG. 6A, the non-volatile memory device 100e includes the pad support vias 328 connected to the lower surface of the pad pattern 330 and the dummy source line layers 210D. The pad support via 328 and the dummy source line layer 210D may correspond to the pad support via SCOT and the dummy source line layer DCL of FIG. 5I.

The dummy source line layers 210D may be spaced apart from each other in the dummy cell region DCR. The dummy source line layers 210D may be spaced apart from each other in horizontal directions (the X direction, the Y direction, and the X-Y direction) with the common source opening 2100 therebetween. A portion of the common source opening 2100, which is between the common source line layer 210 and the dummy source line layer 210D that is closest to the common source line layer 210, may communicate with a portion of the common source opening 2100 located between the dummy source line layers 210D. Each dummy source line layer 210D may overlap at least one dummy structure 230D in the vertical direction (the Z direction). In some embodiments, at least one dummy structure 230D may extend into one of the dummy source line layers 210D through the lower surface of one of the dummy source line layers 210D. Each dummy source line layer 210D may overlap the pad pattern 330 in the vertical direction (the Z direction).

At least one pad support via 328 may be between the pad pattern 330 and each dummy source line layer 210D.

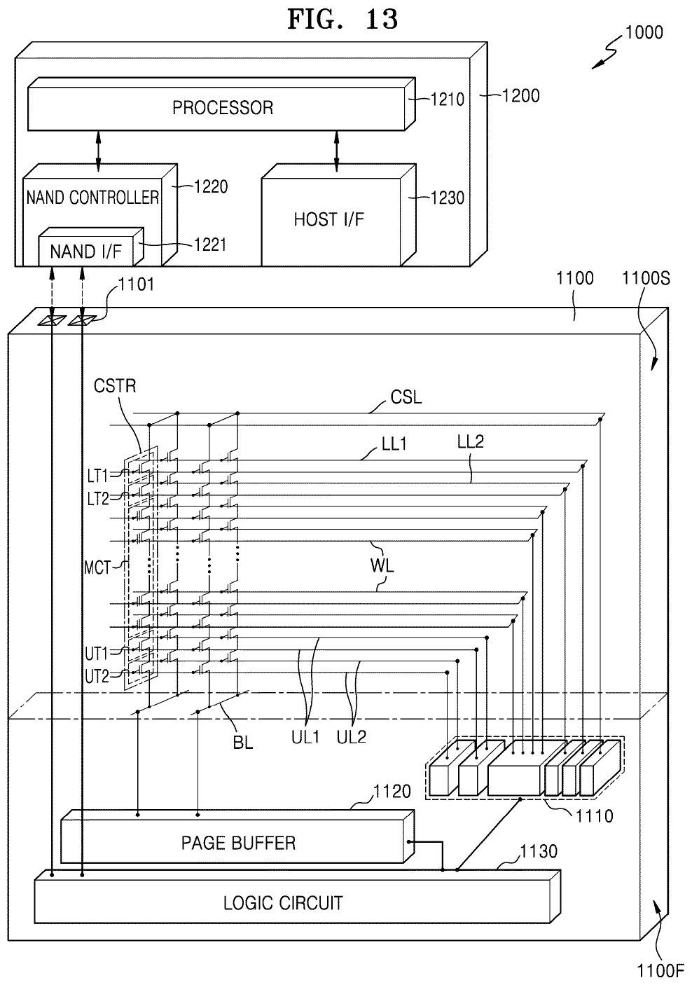

FIG. 13 schematically illustrates a memory system including a non-volatile memory device, according to some embodiments.

Referring to FIG. 13, the memory system 1000 includes one or more memory devices 1100 and a memory controller 1200 electrically connected to the memory devices 1100. The memory system 1000 may be, for example, a solid-state drive (SSD) device, a universal serial bus (USB), a computing system, a medical device, or a communication device, all of which include at least one memory device 1100.

The memory device 1100 may be a non-volatile memory device. For example, the memory device 1100 may be a NAND flash memory device including one of the non-volatile memory devices 1, 1a, 1b, 1c, 1d, 1e, 1f, 1g, 1h, 1i, 100, 100a, 100b, 100c, 100d, and 100e described above with reference to FIGS. 4 to 12 or a combination thereof. The memory device 1100 includes a first structure 1100F and a second structure 1100S on the first structure 1100F. The first structure 1100F may correspond to the peripheral circuit structure PS illustrated in FIGS. 6A, 8, 9, 10, 11, and 12. The peripheral circuit 120 illustrated in FIGS. 6A, 8, 9, 10, 11, and 12 includes a row decoder 1110, a page buffer 1120, and a logic circuit 1130.

The second structure 1100S may correspond to the non-volatile memory devices 1a, 1b, 1c, 1d, 1e, 1f, 1g, 1h, and 1i of FIGS. 5A to 5I and the cell array structure CS of FIGS. 6A, 8, 9, 10, 11, and 12. The second structure 1100S includes the bit line BL, the common source line CSL, the word lines WL, the first string selection line UL1, the second string selection line UL2, the first ground selection line LL1, the second ground selection line LL2, and the memory cell strings CSTR between the bit line BL and the common source line CSL. The cell channel structures 230 and the gate electrodes 222 of FIGS. 6A, 8, 9, 10, 11, and 12 may form the memory cell strings CSTR.

In the second structure 1100S, each memory cell string CSTR includes ground selection transistors LT1 and LT2 adjacent to the common source line CSL, string selection transistors UT1 and UT2 adjacent to the bit line BL, and memory cell transistors MCT arranged between the ground selection transistors LT1 and LT2 and the string selection transistors UT1 and UT2. The number of ground selection transistors LT1 and LT2 and the number of string selection transistors UT1 and UT2 may vary according to embodiments. One of the cell channel structures 230 and one of the gate electrodes 222 illustrated in FIGS. 6A, 8, 9, 10, 11, and 12 may form one of the transistors LT1, LT2, UT1, UT2, and MCT.

In some embodiments, the ground selection lines LL1 and LL2 may be connected to the gate electrodes of the ground selection transistors LT1 and LT2, respectively. The word line WL may be connected to the gate electrode of the memory cell transistor MCT. The string selection lines UL1 and UL2 may be connected to the gate electrodes of the string selection transistors UT1 and UT2, respectively.

The common source line CSL, the ground selection lines LL1 and LL2, the word lines WL, and the string selection lines UL1 and UL2 may be connected to the row decoder 1110. The bit lines BL may be electrically connected to the page buffer 1120.

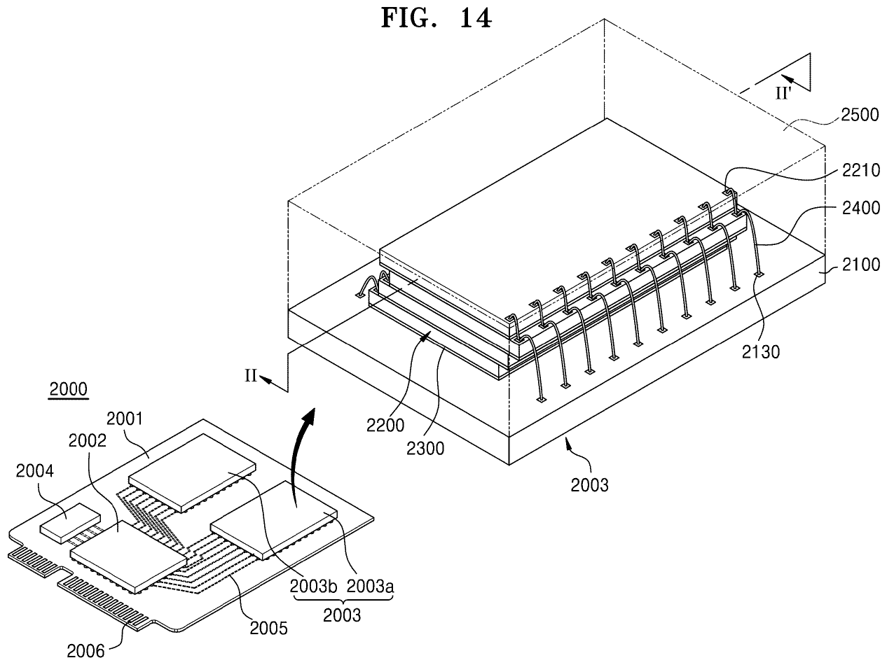

The memory device 1100 may communicate with the memory controller 1200 through an external connection pad 1101 that is electrically connected to the logic circuit 1130. The external connection pad 1101 may be electrically connected to the logic circuit 1130. The external connection pad 1101 may correspond to the pad pattern PAD of FIGS. 5A to 5I and the pad pattern 330 of FIGS. 6A, 8, 9, 10, 11, and 12. The memory device 1100 may be electrically connected to the memory controller 1200 through a connection structure (2400 of FIG. 14) such as a bonding wire connected to the external connection pad 1101.

The memory controller 1200 includes a processor 1210, a NAND controller 1220, and a host interface 1230. In some embodiments, the memory system 1000 includes a plurality of memory devices 1100, and in this case, the memory controller 1200 may control the memory devices 1100.

The processor 1210 may control the overall operations of the memory system 1000 including the memory controller 1200. The processor 1210 may operate according to specific firmware and control the NAND controller 1220 to access the memory device 1100. The NAND controller 1220 includes a NAND interface 1221 processing communication with the memory device 1100. Through the NAND interface 1221, a control command for controlling the memory device 1100, data to be written on the memory cell transistors MCT of the memory device 1100, data to be read from the memory cell transistors MCT of the memory device 1100, and the like may be transmitted. The host interface 1230 may provide a communication function between the memory system 1000 and an external host. When receiving a control command from an external host through the host interface 1230, the processor 1210 may control the memory device 1100 in response to the control command.

FIG. 14 is a schematic perspective view of a memory system including a non-volatile memory device, according to some embodiments.

Referring to FIG. 14, a memory system 2000 according to some embodiments includes a main substrate 2001, a memory controller 2002 mounted on the main substrate 2001, one or more semiconductor packages 2003, and dynamic random access memory (DRAM) 2004. The semiconductor package 2003 and the DRAM 2004 may be connected to the memory controller 2002 by a plurality of wire patterns 2005 formed on the main substrate 2001.

The main substrate 2001 includes a connector 2006 including a plurality of pins coupled to the external host. The number and arrangements of pins in the connector 2006 may differ according to the communication interface between the memory system 2000 and the external host. In some embodiments, the memory system 2000 may communicate with the external host according to any one of interfaces, for example, USB, Peripheral Component Interconnect Express (PCI-Express), Serial Advanced Technology Attachment (SATA), and M-Phy for Universal Flash Storage (UFS). In some embodiments, the memory system 2000 may operate by the power supplied from the external host through the connector 2006. The memory system 2000 may further include a power management integrated circuit (PMIC) configured to distribute power from the external host to the memory controller 2002 and the semiconductor package 2003.

The memory controller 2002 may write data to the semiconductor package 2003 or read data therefrom and may improve the operation speed of the memory system 2000.

The DRAM 2004 may be a buffer memory for reducing a speed gap between the external host and the semiconductor package 2003 that is a data storage space. The DRAM 2004 included in the memory system 2000 may also function as a cache memory and provide a space for temporarily storing data during a control operation performed on the semiconductor package 2003. When the memory system 2000 includes the DRAM 2004, the memory controller 2002 may further include a DRAM controller to control the DRAM 2004, in addition to a NAND controller for controlling the semiconductor package 2003.

The semiconductor package 2003 includes a first semiconductor package 2003a and a second semiconductor package 2003b that are spaced apart from each other. Each of the first semiconductor package 2003a and the second semiconductor package 2003b may be a semiconductor package including a plurality of semiconductor chips 2200. Each of the first semiconductor package 2003a and the second semiconductor package 2003b includes a package substrate 2100, a plurality of semiconductor chips 2200 on the package substrate 2100, an adhesive layer 2300 arranged on a lower surface of each semiconductor chip 2200, a connection structure 2400 configured to electrically connect the semiconductor chips 2200 to the package substrate 2100, and a molding layer 2500 covering, on the package substrate 2100, the semiconductor chips 2200 and the connection structure 2400.

Each semiconductor chip 2200 may include at least one of the non-volatile memory devices 1, 1a, 1b, 1c, 1d, 1e, 1f, 1g, 1h, 1i, 100, 100a, 100b, 100c, 100d, and 100e described with reference to FIGS. 4A to 12. Each semiconductor chip 2200 includes an input/output pad 2210. The input/output pad 2210 may correspond to the pad pattern PAD of FIGS. 5A to 5I and the pad pattern 330 of FIGS. 6A, 8, 9, 10, 11, and 12. The package substrate 2100 may be a printed circuit board including a plurality of package upper pads 2130.

In some embodiments, a connection structure 2400 may be a bonding wire configured to electrically connect the input/output pad 2210 to a package upper pad 2130. Therefore, in the first semiconductor package 2003a and the second semiconductor package 2003b, the semiconductor chips 2200 may be electrically connected to each other in a bonding wire manner and electrically connected to the package upper pad 2130 of the package substrate 2100.

In some embodiments, the memory controller 2002 and the semiconductor chips 2200 may be included in one package. In some embodiments, the memory controller 2002 and the semiconductor chips 2200 may be mounted on an interposer substrate that is different from the main substrate 2001 and may be connected to each other by a wire formed on the interposer substrate.

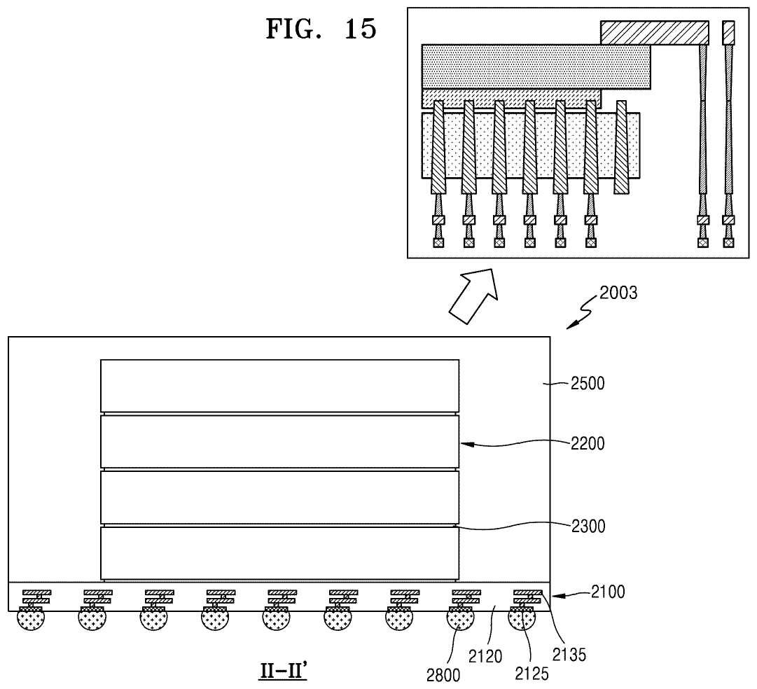

FIG. 15 is a schematic cross-sectional view of a semiconductor package according to some embodiments.

Referring to FIG. 15, in the semiconductor package 2003, the package substrate 2100 may be a printed circuit board. The package substrate 2100 includes a package substrate body portion 2120, a plurality of package upper pads (2130, see FIG. 14) on the upper surface of the package substrate body portion 2120, a plurality of lower pads 2125 arranged on or exposed through the lower surface of the package substrate body portion 2120, and a plurality of internal wires 2135 electrically connecting the package upper pads to the lower pads 2125 inside the package substrate body portion 2120. As shown in FIG. 14, the package upper pads 2130 may be electrically connected to the connection structures 2400. The lower pads 2125 may be connected to the wiring patterns 2005 on the main substrate 2001 of the memory system 2000 of FIG. 14 through conductive bumps 2800. Each semiconductor chip 2200 may include at least one of the non-volatile memory devices 1, 1a, 1b, c, 1d, 1e, 1f, 1g, 1h, 1i, 100, 100a, 100b, 100c, 100d, and 100e described with reference to FIGS. 4A to 12.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the disclosure has been particularly shown and described with reference to embodiments thereof, it will be understood that various changes in form and details may be made therein without departing from the spirit and scope of the following claims.

What is claimed is:

1. A non-volatile memory device comprising:
a peripheral circuit structure comprising a peripheral circuit, a lower insulating structure covering the peripheral circuit, and a plurality of lower bonding pads on an upper surface of the lower insulating structure and electrically connected to the peripheral circuit;
a cell array structure having a cell region and a peripheral connection region, the cell array structure comprising
an upper insulating structure contacting the lower insulating structure,
an upper bonding pad arranged on a lower surface of the upper insulating structure and bonded to the plurality of lower bonding pads,
a cell stack arranged in the cell region of the upper insulating structure,
a common source line layer arranged on the cell stack and comprising a common source opening,
a base insulating layer filling the common source opening and covering the common source line layer, and
a plurality of cell channel structures penetrating the cell stack and extending into the common source line layer; and
a pad pattern extending from the peripheral connection region to the cell region and partially overlapping the common source opening in a vertical direction, wherein the pad pattern is arranged on the cell array structure.

2. The non-volatile memory device of claim 1, wherein the pad pattern does not overlap the common source line layer in the vertical direction.

3. The non-volatile memory device of claim 1,
wherein the cell region comprises a real cell region and a dummy cell region,
wherein the plurality of cell channel structures are arranged in the real cell region and not arranged in the dummy cell region,
wherein the cell stack spans the real cell region and the dummy cell region, and
wherein the pad pattern extends from the peripheral connection region to the dummy cell region.

4. The non-volatile memory device of claim 3, wherein the common source opening is located in the dummy cell region.

5. The non-volatile memory device of claim 3, wherein the common source opening spans the dummy cell region and the real cell region.

6. The non-volatile memory device of claim 3, wherein the cell array structure further comprises at least one dummy structure penetrating the cell stack in the dummy cell region.

7. The non-volatile memory device of claim 6, wherein the cell array structure further comprises a dummy source line layer in the dummy cell region, wherein the dummy source line layer is spaced apart from the common source line layer on the cell stack and arranged in the common source opening, and
a portion of the pad pattern overlaps the dummy source line layer in the vertical direction.

8. The non-volatile memory device of claim 7, wherein the cell array structure further comprises a pad support via arranged between the dummy source line layer and the pad pattern, wherein the pad support via is surrounded by the base insulating layer.

9. The non-volatile memory device of claim 7, wherein the at least one dummy structure extends into the dummy source line layer.

10. The non-volatile memory device of claim 1, wherein the pad pattern overlaps one or more cell channel structures of the plurality of cell channel structures in the vertical direction.

11. A non-volatile memory device comprising:
a peripheral circuit structure comprising a peripheral circuit, a lower insulating structure covering the peripheral circuit, and a plurality of lower bonding pads on an upper surface of the lower insulating structure and electrically connected to the peripheral circuit;
a cell array structure having a cell region and a peripheral connection region, the cell array structure comprising
an upper insulating structure contacting the lower insulating structure,
a plurality of upper bonding pads arranged on a lower surface of the upper insulating structure and respectively bonded to the plurality of lower bonding pads,
a cell stack arranged in the cell region of the upper insulating structure,
a common source line layer arranged on the cell stack in the cell region and comprising a common source opening,
a base insulating layer filling the common source opening and covering the common source line layer,
a plurality of cell channel structures penetrating the cell stack and extending into the common source line layer, and
a through contact plug connected to any one of the plurality of upper bonding pads in the peripheral connection region;
a pad pattern extending from the peripheral connection region to the cell region on the cell array structure, wherein the pad pattern partially overlaps the cell stack in a vertical direction, and wherein the pad pattern does not overlap the common source line layer in the vertical direction; and
a pad connection via connecting between the through contact plug and the pad pattern.

12. The non-volatile memory device of claim 11,
wherein the cell region comprises a real cell region and a dummy cell region,
wherein the plurality of cell channel structures are arranged in the real cell region and not arranged in the dummy cell region,
wherein the dummy cell region is placed between the real cell region and the peripheral connection region,
wherein the cell stack spans the real cell region and the dummy cell region, and
wherein the common source opening is located in the dummy cell region.

13. The non-volatile memory device of claim 12, wherein the cell array structure further comprises, in the dummy cell region, at least one dummy structure penetrating the cell stack and a dummy source line layer, wherein the dummy source line layer is spaced apart from the common source line layer on the cell stack and arranged in the common source opening, and
wherein a portion of the pad pattern overlaps the dummy source line layer in the vertical direction.

14. The non-volatile memory device of claim 13, wherein the cell array structure further comprises a pad support via arranged between the dummy source line layer and the pad pattern, wherein the pad support via is surrounded by the base insulating layer, and
wherein the pad connection via comprises a same material as the pad support via.

15. The non-volatile memory device of claim 13, wherein the cell array structure further comprises a plurality of bit line contacts surrounded by the upper insulating structure and electrically connected to the plurality of upper bonding pads,
one or more bit line contacts of the plurality of bit line contacts each contact a lower surface of each of the plurality of cell channel structures, and
a lower surface of the at least one dummy structure is covered by the upper insulating structure.

16. The non-volatile memory device of claim 13, wherein the pad pattern extends from the peripheral connection region to the dummy cell region and overlaps the at least one dummy structure in the vertical direction.

17. The non-volatile memory device of claim 12, wherein the common source opening spans the dummy cell region and the real cell region.

18. A memory system comprising:
a non-volatile memory device; and
a memory controller electrically,
wherein the non-volatile memory device comprises a peripheral circuit structure, a cell array structure bonded to the peripheral circuit structure, and a pad pattern,
wherein the peripheral circuit structure comprises a peripheral circuit, a lower insulating structure covering the peripheral circuit, and a plurality of lower bonding pads arranged on an upper surface of the lower insulating structure and electrically connected to the peripheral circuit,
wherein the cell array structure comprises a cell stack region and a peripheral circuit region,
wherein the cell stack region comprises a real cell region and a dummy cell region,
wherein the pad pattern extends on the cell array structure from the peripheral connection region to the dummy cell region,
wherein the cell array structure further comprises
an upper insulating structure contacting the lower insulating structure,
a plurality of upper bonding pads arranged on a lower surface of the upper insulating structure and respectively bonded to the plurality of lower bonding pads,
a cell stack arranged in the cell stack region of the upper insulating structure,
a common source line layer arranged on the cell stack, comprising a common source opening in the dummy cell region, and not overlapping the pad pattern in a vertical direction,
a base insulating layer filling the common source opening and covering the common source line layer,
a plurality of cell channel structures penetrating the cell stack in the real cell region and extending into the common source line layer,
a through contact plug electrically connecting, in the peripheral connection region, between the pad pattern and at least one upper bonding pad of the plurality of upper bonding pads, and
a pad connection via connecting between the through contact plug and the pad pattern.

19. The memory system of claim 18, wherein a portion of the pad pattern overlaps the common source opening in the vertical direction and covers a portion of the base insulating layer.

20. The memory system of claim 18, wherein the cell array structure further comprises at least one dummy structure penetrating the cell stack in the dummy cell region,
the plurality of cell channel structures are electrically connected to one or more upper bonding pads of the plurality of upper bonding pads,
the dummy structure is not electrically connected to the plurality of upper bonding pads, and
the upper insulating structure covers a lower surface of the dummy structure.
